(19) United States
(12) Patent Application Publication
(10) Pub. No.: US 2026/0063832 A1
(43) Pub. Date: Mar. 5, 2026

(54) WORKPIECE WITH A HOLLOW STRUCTURE, METHOD FOR AT LEAST PARTIALLY FORMING A HOLLOW STRUCTURE, MIRROR, AND LITHOGRAPHY SYSTEM

(71) Applicant: Carl Zeiss SMT GmbH, Oberkochen (DE)

(72) Inventors: Eric EVA, Aalen (DE); Erik LOOPSTRA, Ederheim Huernheim (NL); Tobias ULLSPERGER, Erfurt (DE); Stefan NOLTE, Jena (DE); Caren MOELLER, Goeppingen (DE); Werner PETZOLD, Gerstetten (DE)

(21) Appl. No.: 19/385,738

(22) Filed: Nov. 11, 2025

Related U.S. Application Data
(63) Continuation of application No. PCT/EP2023/062807, filed on May 12, 2023.

(51) Int. Cl. G02B 5/08; B23K 26/0622; B23K 26/55; B23K 103/00; G03F 7/00

(52) U.S. Cl. CPC G02B 5/0891; B23K 26/0624; B23K 26/55; G02B 5/0808; G03F 7/702; G03F 7/70233; G03F 7/70891; G03F 7/70958; B23K 2103/54

(57) ABSTRACT

A workpiece having: at least one hollow structure (27) which runs in the workpiece (25) and configured to receive a flowing fluid (28) therein. The hollow structure has a first section and a second, adjacent section, which are mutually oriented at an angle (γ) of between 60° and 120°. The hollow structure has a rounded-off section (37a, 37b), at which the first section and the second section merge into one another. A surface of a wall of the hollow structure in the first section, in the second section and/or in the rounded-off section has a roughness Rₐ of 25 μm or less. Also, a method for at least partly forming a hollow structure in a workpiece by selective laser-induced etching, an associated mirror (24), and an associated reflective coating (26), applied to a surface (25a) of the substrate.

### CROSS-REFERENCE TO RELATED APPLICATION

This is a Continuation of International Application PCT/EP2023/062807, which has an international filing date of May 12, 2023, and the disclosure of which is incorporated in its entirety into the present Continuation by reference.

### FIELD

The invention relates to a workpiece, preferably a substrate for a mirror, in particular a substrate for a mirror configured for operation with extreme ultraviolet (EUV) radiation, comprising: at least one hollow structure which runs in the substrate and which is configured to allow a fluid to flow through it. The invention also relates to a method for at least partly forming a hollow structure in a workpiece. The invention also relates to a mirror, in particular an EUV mirror, which comprises a workpiece in the form of a substrate configured as described further above. The invention further relates to a lithography system, in particular an EUV lithography system, comprising: at least one mirror configured as described further above and a temperature control device, in particular a cooling device, which is configured to cause a temperature control fluid, in particular a cooling fluid, to flow through the at least one hollow structure.

### BACKGROUND

The lithography system can be a lithography apparatus for exposing a wafer or some other optical arrangement used for lithography, for example an inspection system, e.g. an arrangement for measuring or inspecting masks, wafers or the like that are used in lithography. The lithography system can be configured for example for operation with radiation in the extreme ultraviolet (EUV) wavelength range. In the context of this application, the EUV wavelength range is understood to be a wavelength range between approximately 5 nm and approximately 30 nm.

In an EUV lithography system in the form of an EUV lithography apparatus, optical elements for reflecting radiation in the form of mirrors, in particular in the form of mirrors of a projection system, are exposed to a high radiation power. As the EUV radiation sources have more power, the mean powers radiated onto the mirrors may be as much as 50 W, a third to a half of which is absorbed in the layer system of the reflective coating and leads to extensive and local heating of the mirror or substrate. Even if so-called zero expansion material, e.g. in the form of titanium-doped fused silica, or in the form of a glass ceramic, is used, this heating leads to shape changes of the surface of the mirror to which the reflective coating is applied. These shape changes are attributable, inter alia, to inhomogeneities in the (linear) coefficient of thermal expansion (CTE) or the zero crossing temperature (TZC) within the volume of the substrate, and to the fact that the coefficient of thermal expansion differs significantly from zero away from the zero crossing temperature.

In order to reduce the temperature of the mirrors of EUV lithography systems, it is known to introduce hollow structures in the form of cooling channels into the substrate of the mirrors and to cause a cooling fluid to flow through the hollow structures in the form of the cooling channels. Such channels can be milled into the substrate and closed with a cover during production.

On account of the suspended mount of the mirrors and the generally disadvantageous effect on image aberrations, turbulent flows and vibrations attributable to the flow of the (generally liquid) cooling medium (“flow-induced vibrations”, FIV) should be avoided. However, the inner sides of the milled channels are generally angular and rough, which is disadvantageous in relation to FIV.

With selective laser-induced etching (SLE), it is possible to produce micro-channels, profiled bores, etc. in transparent components, for example made of fused silica, borosilicate glass, sapphire or ruby. In selective laser-induced etching, light in the form of ultrashort pulsed laser radiation (ps or fs pulses) is focused in the volume of a transparent workpiece (focus volume). In this case, the pulse energy is only absorbed within the focus volume as a result of multi-photon processes. In the focus volume, the optical and chemical properties of the transparent material are changed, without cracks or possibly with microcracks, such that it is rendered selectively chemically etchable. Depending on the laser parameters used, the modification of the material can be microcracks or other damage at depth. By deflecting the focus in the material, for example with a microscanner system, contiguous regions (contiguous irradiation volumes) are modified and these can subsequently be removed through wet chemical etching. In the case of wet chemical etching, the component is typically immersed in an etching solution over several weeks or months, the etching solution preferably (selectively) removing the modified material. Any desired hollow structures, for example in the form of channels, can be produced by the scanning or the movement of the laser radiation in the volume of the workpiece.

A limiting factor for the selective laser-induced etching of channels in fused silica and also other materials, e.g. in titanium-doped fused silica, is the comparatively low etching selectivity of approximately 1:500 to approximately 1:1500 in comparison with other transparent materials, e.g. sapphire, which has an etching selectivity of 1:10000. The low etching selectivity leads to the channel, during etching, having a wider form in a region at the edge of the component, which is attacked first by the etching liquid, than further inside the volume of the component. The regions that are too wide may lead to inhomogeneous cooling of the component and may possibly carry through mechanically: In extreme cases, too strong etching may lead to short circuits between adjacent channels. Generally, the conical channel cross-section that arises when etching selectivity is deficient is not desirable either.

WO2021/115643 A1 describes an optical element for reflecting EUV radiation in which at least one channel is formed in the substrate, a cooling medium preferably being able to flow through the at least one channel. The substrate is formed from fused silica, in particular from titanium-doped fused silica, or from a glass ceramic. The channel has a length of at least 10 cm and a cross-sectional area of the channel varies over the length of the channel by not more than +/−20%. WO2021/115643 A1 describes that a channel having such properties is typically produced by selective laser-induced etching, wherein the etching selectivity should be increased in order to produce such a channel. The inside of such a channel may have a low roughness.

DE102019200750A1 describes a method for producing components of a projection exposure apparatus for semiconductor lithography, wherein a hollow structure is produced in the component, e.g. in a mirror body, by selective laser-induced etching. The hollow structure can be configured as a temperature control channel which runs in a temperature control plane between two perforations which are oriented perpendicular to the temperature control plane and serve as inlet and outlet for the temperature control fluid. The temperature control channel is connected to the perforations via two angular 90° bends.

### SUMMARY

It is an object of the invention to provide a workpiece, a mirror and a lithography system in which flow-induced vibrations caused when a fluid flows through the hollow structure are reduced.

According to one formulation, this object is achieved by a workpiece of the type mentioned in the introduction in which the hollow structure has a first section and a second, adjacent section, which are oriented at an angle of between 60° and 120°, preferably at an angle of between 80° and 100°, in particular at an angle of 90°, with respect to one another, wherein the hollow structure has a rounded-off section, at which the first section and the second section merge into one another, and wherein a surface of a wall of the hollow structure in the first section, in the second section and/or in the rounded-off section has a roughness Rₐ of 25 μm or less, preferably of 10 μm or less, particularly preferably of 5 μm or less, in particular of 2 μm or less. The roughness Rₐ, also called mean roughness, indicates the mean distance of a measurement point on the surface with respect to the mean line of the surface. The mean roughness thus corresponds to the arithmetic mean of the deviation—in terms of absolute value—from the mean line.

The inventors have recognized that given the typical flow velocities at which the fluid flows through the hollow structure, a flow separation that leads to turbulence and causes flow-induced vibrations arises at the wall of the hollow structure at a transition between two sections of the hollow structure of the workpiece in the form of a corner or a sharp edge, especially if the two sections are oriented approximately perpendicular (i.e. at an angle of between 60° and 120°) with respect to one another. For this reason, it is proposed that the two sections of the hollow structure merge into one another at a rounded-off section, which has a profile that is as streamlined as possible.

A rounded-off section is understood to mean a section without corners. Consequently, the first section merges continuously into the second section at the rounded-off section. The cross-section or the diameter of the hollow structure is typically constant within the rounded-off section, but optionally it may also vary. As a rule, the cross-section or the diameter of the rounded-off section corresponds to the cross-section of the two sections, but this is not absolutely the case if the rounded-off section is arranged at a branching point (see below).

The hollow structure having the rounded-off section can be produced wholly or partly by selective laser-induced etching. The hollow structure has a wall that forms the interface between the interior of the hollow structure and the material of the workpiece. Particularly during the production of the hollow structure by selective laser-induced etching, it is possible to attain a low roughness of the surface of the wall of the hollow structure, which counteracts the arising of flow-induced vibrations. This is advantageous especially in the rounded-off section described further above. As a rule, both the rounded-off section and the first section and the second section satisfy the condition for roughness specified above.

For the production of the workpiece described further above, it is advantageous in particular if the etching selectivity is increased during selective laser-induced etching. The etching selectivity can be increased in various ways, for example by the etching front being tracked by a flexible hose. The rounded-off section facilitates tracking by such a flexible hose. Since, if the surface of the wall of the hollow structure has an excessively high microscopic roughness, the hose may get caught in particular on the rounded-off section on the wall, the low roughness of the surface of the wall of the hollow structure also facilitates tracking by such a hose.

In one embodiment, the surface of the wall of the hollow structure has cutouts. The surface of the wall facing the interior of the hollow structure in this case has a surface structure having cutouts, which are also referred to hereinafter as depressions or as recesses and which typically have a concave course.

In one development of this embodiment, the cutouts are configured in crater-shaped fashion. In the context of this application, a crater-shaped cutout is understood to mean a recess or cutout whose base is enclosed by a ring-shapedly elevated wall, which is also referred to hereinafter as crater edge. The crater-shaped cutout can have a geometry that is substantially circular in plan view, but it is also possible for the cutout to have in plan view a geometry that deviates from a circular geometry, for example a polygonal geometry, an angular geometry, etc.

In one further development, adjacent cutouts on the wall of the hollow structure run over into one another. The number of cutouts on the surface and the lateral extent thereof are typically large enough that adjacent cutouts run over into one another. For the case where the cutouts are configured in crater-shaped fashion, a respective crater edge which encloses a cutout, on its side facing away from the cutout, forms a section of a crater edge of an adjacent cutout or merges into the base of an adjacent cutout. In this development, adjacent cutouts do not just adjoin one another, but rather at least partly mutually overlap one another.

In a further development, the cutouts on the surface of the wall of the hollow structure form a honeycomb-like surface structure. As has been described further above, adjacent cutouts typically rather than just adjoining one another, as is also the case for bees' honeycombs, run over into one another. In contrast to bees' honeycombs, the cutouts are generally also not arranged in a regular grid. The shape and size of the cutouts forming the honeycomb-like surface structure vary as well. The edges between two adjacent cutouts, which can be configured in particular in the form of crater edges, generally form a netlike surface structure complementary to the honeycomb structure.

In one development, the cutouts have a maximum lateral extent of not more than 500 μm, preferably of not more than 450 μm, in particular of not more than 400 μm. The maximum lateral extent is understood to mean the maximum lateral distance between two points along the edge of the cutout in plan view of the cutout. In the case of a crater-shaped cutout, the maximum lateral extent denotes the maximum lateral distance between two points on the respective crater edge.

In a further development, the cutouts have a maximum depth of not more than 20 μm, preferably of not more than 15 μm, in particular of not more than 10 μm. The maximum depth is understood to mean the distance in the height direction that is measured between the base of the cutout and the highest point on the edge of the cutout or on the crater edge.

The surface of the wall of the hollow structure can be planar, for example if the hollow structure has a channel having a rectangular or square cross-section. For the case where the surface of the wall of the hollow structure has a curvature, for example because the hollow structure forms a channel having a circular cross-section, it is assumed for the determination of the lateral distance and the depth of the cutouts that the surface of the hollow structure runs in approximately planar fashion in the partial region used for the measurement. If necessary, the development of the e.g. cylindrical surface forming the lateral surface of the channel can be used for determining the lateral distance and the depth of the cutouts.

In a further embodiment, the first section, the second, adjacent section and the rounded-off section each form a channel section of a channel through which a fluid is able to flow. A channel through which a fluid or a liquid is able to flow forms an elongated cavity that is closed in the circumferential direction, the cavity having no branching points and extending between a first end of the channel and a second end of the channel. At one or both ends, the channel can merge into further hollow structures located in the volume of the workpiece. It is also possible for one or both ends of the channel to open up on the outer side of the workpiece. In this case, the cross-section or the diameter of the rounded-off section generally substantially corresponds to the cross-section of both sections of the channel. The wall of the hollow structure forms the lateral surface of the channel in this case.

In one development of this embodiment, the channel has a diameter of between 1 mm and 20 mm, preferably between 1 mm and 5 mm, and/or a length of at least 10 cm, preferably at least 15 cm, in particular at least 20 cm. The channel can have a round cross-section, but the channel can also have a cross-section that deviates from a round geometry. In this case, the diameter of the channel is understood to mean the so-called equivalent diameter, that is to say the diameter of a circle whose area corresponds to the cross-section of the channel, which is not circular in this case. For the flow of a fluid, channels with a diameter in the aforementioned value range have proved to be advantageous.

Particularly for the case where the workpiece has a large volume, it is advantageous if the channel has a comparatively long length. The diameter of the channel can optionally vary in the longitudinal direction of the channel, but it is generally advantageous if the diameter of the channel varies as little as possible in the longitudinal direction.

In one embodiment, the cross-sectional area of the channel varies over the length of the channel by not more than +/−20%, preferably by not more than +/−10%, in particular by not more than +/−2%. In this embodiment, the channel typically has a length of at least 10 cm, preferably of at least 15 cm, in particular of at least 20 cm. In the context of this application, a variation of the cross-sectional area of the channel of +/−x % is understood to mean a deviation by +/−x % from a mean cross-sectional area AM of the channel. The mean cross-sectional area AM is defined as the mean of the maximum cross-sectional area AMAX and the minimum cross-sectional area AMIN along the length of the channel (AM=(AMAX+AMIN)/2), as described in WO2021/115643 A1, cited in the introduction, the entirety of which is incorporated by reference in the content of this application.

In one embodiment, an R/D ratio between a radius of curvature R of the rounded-off section and a diameter D of the rounded-off section is between 2 and 6, preferably between 2.5 and 5, in particular between 2.5 and 3.5. Significant improvements in relation to the flow-induced vibrations, for example >50%, can already be achieved in the case of an R/D ratio of more than 2. Ideally, the R/D ratio is between approximately 2.5 and 3.5, for example 3.0, since the greatest improvements in relation to the flow-induced vibrations are typically attained there. The R/D ratio should not exceed a value of more than 6. In this embodiment, the rounded-off section has a constant radius of curvature.

The flow cross-section of the rounded-off section is typically circular but can optionally deviate from a circular geometry and for example have an elliptical geometry. In this case, the diameter of the rounded-off section is understood to mean the so-called equivalent diameter which has been defined further above.

It has been found that the ratio between the diameter of the rounded-off section and the radius of curvature of the rounded-off section represents an important parameter for a streamlined flow guidance without turbulence, and consequently for the avoidance of flow-induced vibrations.

In a further embodiment, the diameter D of the rounded-off section is between 2 mm and 20 mm, preferably between 2 mm and 12 mm. A diameter of the rounded-off section or of the channel structures of the hollow structure of the specified order of magnitude allows the generation of a sufficient volumetric flow rate for efficient temperature control of the optical element for the given boundary conditions. The flow velocity of the fluid in the hollow structure is generally of the order of magnitude of meters per second.

In one embodiment, the hollow structure comprises a plurality of temperature control channels which run below a surface of the workpiece, and the hollow structure comprises a fluid distributor connected to the temperature control channels via distributor channels and a fluid collector connected to the temperature control channels via collector channels. The temperature control channels usually serve for cooling the workpiece and are therefore also referred to hereinafter as cooling channels.

The temperature control channels generally run in a superficial region below a surface, which is generally a surface whose temperature is to be controlled. A superficial region is understood to mean a distance of 10 mm or less from the surface of the workpiece whose temperature is to be controlled. The distance from the surface whose temperature is to be controlled is measured in the thickness direction of the workpiece, which direction is oriented perpendicular to the surface of the workpiece whose temperature is to be controlled and below which the temperature control channels run. Effective cooling of the surface of the workpiece whose temperature is to be controlled can be brought about as a result of the small distance of the cooling channels from the surface whose temperature is to be controlled. The distance is understood to mean the minimum distance between the respective temperature control channel and the surface of the workpiece whose temperature is to be controlled.

As a rule, the fluid distributor and the fluid collector each have a greater flow cross-section than an individual cooling channel. This makes the setting of beneficial flow conditions possible. The fluid distributor and/or the fluid collector are/is preferably arranged at a greater distance from the surface whose temperature is to be controlled than the cooling channels. This arrangement allows the deformation of the surface owing to the fluid pressure in the fluid distributor and/or in the fluid collector, which generally have cavities with a greater surface area than the cooling channels, to be kept within acceptable limits. The fluid distributor is typically connected to a fluid inlet and the fluid collector is typically connected to a fluid outlet. Each respective cooling channel can be connected to precisely one distributor channel and to precisely one collector channel; however, as a matter of principle, it is also possible for a group of two or optionally more than two cooling channels to be connected to a common distributor channel and to a common collector channel.

In a further embodiment, the first section forms an end section of the temperature control channel adjoining a distributor channel and the second section forms a distributor channel section adjoining the end section and/or the first section forms an end section of the temperature control channel adjoining a collector channel and the second section forms a collector channel section adjoining the end section.

The cooling channels typically run substantially parallel to the surface whose temperature is to be controlled and on which, for the case where the workpiece is a substrate for a mirror, a reflective coating is applied. Since the installation space within the substrate is limited, a distributor channel or a collector channel, which is connected to a respective cooling channel, is generally led away from the surface with the reflective coating at an approximately right angle, that is to say the collector or the distributor channel section and an adjacent end section of the cooling channel typically run approximately at a right angle to one another, that is to say there is approximately a 90° deflection of the fluid which flows through the hollow structure.

The rounded-off section described further above allows avoidance of, or at least substantial reduction in, flow-induced vibrations in this region, in particular with the choice of a suitable ratio of radius of curvature to diameter.

In principle, the fluid distributor and the fluid collector can be configured in various ways. By way of example, the flow cross-section of the fluid distributor and of the fluid collector can taper starting from the distributor channels and from the collector channels, respectively, for example in the style of a funnel, such that the cavities formed by the fluid distributor and the fluid collector in the workpiece are not unnecessarily large.

In a further embodiment, the fluid distributor forms an inlet channel, from which the distributor channels branch off, and/or the fluid collector forms an outlet channel, from which the collector channels branch off. In this embodiment, the fluid collector and the fluid distributor generally run substantially transversely to the longitudinal direction of the distributor channels and transversely to the longitudinal direction of the collector channels. As a rule, the distributor channels and the collector channels branch off from the inlet channel and the outlet channel, respectively, substantially at right angles. for instance, the fluid distributor and the fluid collector can in this case be configured in the form of cylindrical channels which extend into the workpiece starting from an inlet opening and from an outlet opening, respectively, on an outer side of the workpiece. In this case, the inlet channel and the outlet channel can be configured in the form of drilled holes, for example; however, it is also possible for these to be produced by selective laser-induced etching described further above.

In one development of this embodiment, the first section forms a merging section of the distributor channel adjacent to the inlet channel, and the second section forms a branching section of the inlet channel adjacent to the merging section, and/or the first section forms a merging section of the collector channel adjacent to the outlet channel, and the second section forms a branching section of the outlet channel adjacent to the merging section of the collector channel.

As has been described further above, the longitudinal direction of the inlet channel and of the outlet channel runs substantially perpendicular to the longitudinal direction of a respective collector channel and distributor channel, respectively. At a respective branching point of a distributor or collector channel, a streamlined geometry which can be produced by the provision of a rounded-off section at a branching point of the inlet channel or of the outlet channel is also advantageous. Steps can be avoided and edges can be rounded-off in this way, as a result of which the geometry of the hollow structure can be designed in more streamlined fashion and the separation of the fluid in the inlet channel and in the outlet channel can be avoided or at least significantly reduced.

The ratio of diameter to radius of the rounded-off section is preferably within the value range described above. However, the rounded-off section may not have a constant radius of curvature at the branching point. The flow diameter of the rounded-off section at the branching point need not necessarily be constant either. By way of example, the cross-section of the rounded-off section can taper starting from the inlet channel or starting from the outlet channel.

In a further embodiment, the angle between the branching section of the inlet channel and the merging section of the distributor channel is greater than 90°, preferably greater than 100°, and/or the angle between the branching section of the outlet channel and the merging section of the collector channel is greater than 90°, preferably greater than 100°. It has been found that it is beneficial to the flow guidance if the branching section of the inlet channel and of the outlet channel and the merging section of the distributor channel and of the collector channel, respectively, are oriented at an obtuse angle with respect to one another.

A further aspect of the invention relates to a workpiece of the type mentioned in the introduction in which a surface of a wall of the hollow structure has cutouts. In this case, the hollow structure is typically produced by selective laser-induced etching. The wall of the hollow structure has a characteristic surface structure having cutouts, which is configured as described further above, as will be explained in specific detail again below:

In one embodiment, the cutouts are configured in crater-shaped fashion.

In a further embodiment, adjacent crater-shaped cutouts run over into one another.

In a further embodiment, the cutouts on the surface of the wall of the hollow structure form a honeycomb-like structure.

In a further embodiment, the cutouts each have a maximum lateral extent of not more than 500 μm, preferably of not more than 450 μm, in particular of not more than 400 μm.

In one embodiment, the cutouts have a maximum depth of not more than 20 μm, preferably of not more than 15 μm, in particular of not more than 10 μm.

In one embodiment, the surface of the wall of the hollow structure has a roughness Rₐ of 25 μm or less, preferably of 10 μm or less, particularly preferably of 5 μm or less, in particular of 2 μm or less.

In one embodiment, the hollow structure is configured in the form of a preferably curved channel through which a fluid is able to flow.

In one development of this embodiment, the channel has a diameter of between 1 mm and 20 mm, preferably between 1 mm and 5 mm, and/or a length of at least 10 cm, preferably at least 15 cm, in particular at least 20 cm.

In a further development of this embodiment, a cross-sectional area of the channel varies over the length of the channel by not more than +/−20%, preferably by not more than +/−10%, in particular by not more than +/−2%.

In both aspects described further above, the material of the workpiece is preferably selected from the group comprising: fused silica, in particular titanium-doped fused silica, and glass ceramic. In this case, the workpiece is typically a substrate for a mirror, more precisely a substrate for an EUV mirror. In order to avoid deformations of the surface to which in this case a reflective coating is applied, which deformations are attributable to possibly inhomogeneous heating of the material of the workpiece, the substrates of mirrors for EUV lithography are typically produced from so-called zero expansion material which has a very small coefficient of thermal expansion. As has been described further above, these materials are hard and brittle and can therefore be mechanically processed only with difficulties. However, hollow structures of practically any shape can also be produced in such materials using the method for selective laser-induced etching described further above.

In a further embodiment, the material of the workpiece has a zero crossing temperature which is between 0° C. and 100° C., preferably between 19° C. and 40° C., particularly preferably between 19° C. and 32° C. The zero crossing temperature is defined, inter alia, depending on the mean incident radiation power during the operation of an EUV mirror.

In one embodiment, the material of the workpiece has a spatial variation of the zero crossing temperature which is less than 3 K, preferably less than 2 K, particularly preferably less than 1 K, in particular less than 0.1 K. A high spatial homogeneity of the zero crossing temperature is typically required to be able to efficiently operate an EUV mirror.

In a further embodiment, the workpiece is monolithic, that is to say it is formed in one piece and has no joining surface at which two or more partial bodies of the workpiece are interconnected. A rounded-off section in a monolithic workpiece cannot be straightforwardly produced by mechanical processing, e.g. by drilling or by milling, in the hard and brittle glass material. In principle, it is also possible for the workpiece to be composed of two or more partial bodies. In this case, the joining surface typically does not run through the rounded-off section, i.e. the joining surface does not intersect the rounded-off section.

A further aspect of the invention relates to a method for at least partly forming a hollow structure in a workpiece, in particular in a workpiece configured as described further above, by selective laser-induced etching, wherein the method comprises: focusing pulsed laser radiation into a typically contiguous irradiation volume in the workpiece, and at least partly forming the hollow structure by selectively etching the workpiece in the irradiation volume.

As has been described further above, the hollow structure can be formed wholly or only partly, in particular sectionally, by selective laser-induced etching. In particular, the first section described further above, the second section and/or the rounded-off section of the hollow structure, e.g. in the form of channel sections, can be formed by selective laser-induced etching. It is assumed for simplification hereinafter that the hollow structure formed in the method is a channel.

As has been described further above, the etching process takes place proceeding from the edge or from the surface of the workpiece into the irradiation volume of the workpiece. The etching forms a channel section which extends in the irradiation volume proceeding from entry into the channel section on the surface of the workpiece as far as an end face of the channel section at which an etching front is formed. At the etching front or at the end face, further material of the workpiece is gradually ablated along the irradiation volume until the channel has been completely formed, i.e. until the channel extends over the entire irradiation volume. During the etching process, the length of the channel section already etched is thus gradually increased, in a manner comparable to the drilling of a tunnel.

As has likewise been described further above, depending on the material of the workpiece in which the channel is formed, the etching selectivity in the irradiation volume vis-à-vis the non-irradiated volume of the workpiece is comparatively low and may be just 1:500. This results in the channel having a wider form at the edge of the workpiece, which is attacked first by the etching liquid, than further inside the volume of the workpiece since the period of time during which the channel wall in the volume of the workpiece is exposed to the etching medium is significantly shorter than at the edge of the workpiece.

This problem can be combated by a procedure in which an end face of a channel section formed in the irradiation volume during the selective laser-induced etching is etched with a higher etching rate than a (circumferential, already etched) channel wall of the channel section.

Preferably, the ratio of the etching rate at the channel wall of the channel section to the etching rate at the end face of the channel section or the etching selectivity is at least 1:1500, particularly preferably at least 1:2000. In the context of this application, increasing the etching selectivity is understood to mean that the ratio described above decreases, that is to say that the etching rate at the end face of the channel section increases vis-à-vis the etching rate at the channel wall. With the exception of the case described further below where the channel wall is sealed against etching, increasing the etching rate at the end face of the channel relative to the etching rate at the channel wall leads to a higher etching rate overall.

In this way, a channel having a possibly considerable length can be formed in the workpiece, wherein the cross-sectional area of the channel, over the length of the channel, is substantially constant or varies only slightly, specifically by not more than +/−20%, optionally by not more than +/−10% or +/−2%. This also holds true if the workpiece is a substrate e.g. for a reflective optical element formed from fused silica, in particular from titanium-doped fused silica, or from a glass ceramic, as described in WO2021/115643 A1. The workpiece, which for example can be a substrate for a reflective optical element, can be configured in particular in monolithic fashion (see above).

For increasing the etching rate at the end face vis-à-vis the etching rate at the channel wall, which is advantageous or necessary in order to produce a cross-section that is substantially constant over the length of the channel, various measures can be implemented individually or in combination.

One such measure consists in producing, for increasing the etching rate, a temperature at the end face of the channel section which is at least 20 K, preferably at least 40 K, in particular at least 60 K, greater than a temperature at the channel wall of the channel section. The etching selectivity is increased in this case by the workpiece and the etching solution or the etching liquid being kept at the lowest possible temperature that is just above or optionally just below the freezing point of the etching solution. By contrast, the etching front at the end face of the channel is kept at the highest possible temperature that is at least 20 K, preferably at least 40 K, ideally at least 60 K, higher than the temperature of the etching solution and the (rest of the) workpiece and thus also the temperature at the (circumferential) channel wall of the channel section.

In this case, the end face of the channel section can be heated with at least one heating device, which is preferably guided concomitantly with the end face of the channel section during the formation of the channel. As has been described further above, during the formation of the channel, the position of the end face of the channel or of the etching front changes, i.e. this moves along the entire length of the irradiation region. In order to produce the higher temperature at the etching front/end face in comparison with the surrounding material of the workpiece, it is therefore advantageous to guide the heating device concomitantly with the etching front.

The heating device can be situated outside the channel, e.g. on or in the vicinity of that surface of the workpiece which is at the least distance from the channel. In this case, the heating device can be guided concomitantly for example along the surface parallel to the channel or the etching front in the channel. In this case, the heating device can be e.g. a resistance heater that is in contact with the surface in order to transfer contact heat to the material of the workpiece. However, the heating device can also be a heating light source, for example an infrared light source, or a laser that is focused onto the etching front along the direction of the channel or of the channel section or is optionally focused through the material of the workpiece onto the end face of the channel section. It is also possible to guide or thread the heating device (e.g. in the form of a resistance heater or a light source) through the channel section and to keep the heating device ideally at a constant distance from the etching front. In this case, the heating device can be mounted on a suitable carrier element having a smaller dimensioning than the channel diameter. Such a carrier element is referred to hereinafter as a probe.

In a further measure, for increasing the etching rate, the end face of the channel section is exposed to an increased throughput of an etching solution by comparison with the channel walls. The throughput of the etching solution at the end face of the channel section can be increased by swirling the etching solution, for example. For this purpose, for example, a probe can be inserted into the channel section permanently or (periodically) intermittently. The probe can have a swirling device, e.g. in the form of a propeller, a turbine or the like, in order to swirl the etching solution and to increase the throughput of the etching solution at the etching front in this way.

In a further measure, for increasing the etching rate, the end face of the channel section is mechanically freed of initially etched particles. For increasing the etching rate at the end face of the channel section, it is possible in this case to use a nozzle which is arranged permanently or intermittently in front of the entrance of the channel section or which is inserted into the channel section permanently progressively or intermittently with the aid of a probe or a fluid feed device, e.g. in the form of a hose. Owing to the fact that at the channel wall the surrounding, non-irradiated material of the workpiece is etched, the flow of the etching solution that is produced with the aid of the nozzle removes more initially etched particles from the end face of the channel section than from the channel wall. As an alternative or in addition to the nozzle, a probe can also comprise a mechanical stirrer, a brush, or the like, which is positioned in the vicinity of the etching front or is guided concomitantly therewith in order to remove particles etched free.

In a further measure, for reducing the ratio of the etching rate at the channel wall of the channel section to the etching rate at the end face of the channel section, i.e. for increasing the etching selectivity, the end face of the channel section is exposed to ultrasonic waves. The effect of the ultrasound or the ultrasonic waves can consist in detaching initially etched particles, in recirculating the etching solution and/or in a heating effect on the etching front. In order to expose the end face of the channel section to ultrasound, it is possible to use an ultrasound generator which is arranged outside the workpiece and which radiates the ultrasonic waves through a surface of the workpiece that is adjacent to the channel section onto the end face of the channel section. Alternatively or additionally, an ultrasound generator on a probe can be inserted into the channel section in order to expose the end face of the channel section to the ultrasonic waves.

In a further measure, for increasing the etching rate, the channel wall of the channel section is sealed against etching, wherein a protective lacquer is preferably applied to the channel wall during sealing. In this variant, the already etched channel section at the circumferential channel wall—but not at the end face—is sealed against etching by the etching solution. For sealing purposes, it is possible to use a lacquer, for example a polymer lacquer, which has a protective effect against etching and is not attacked, or is only slightly attacked, by the etching solution. For sealing purposes, it may be appropriate for the workpiece, periodically, for example daily, to be removed from the etching bath or from the etching solution and rinsed and dried in order to seal a channel section that has been newly etched during the day. Alternatively, it is also possible to remove the entire previous sealing of the channel section by the use of an organic solvent, for example, and a new sealing can be applied, extending to just before the etching front or just before the end face of the channel.

The sealing can be applied by the workpiece being dipped into a protective lacquer. In this case, it is necessary to leave free the end face of the channel section that forms the later etching front. This can be done by insertion of a probe and mechanical cleaning or irradiation using (laser) light in order to remove the lacquer from the end face. A UV-curing lacquer can also be used. In this case, a probe that radiates toward the side, i.e. toward the circumferential channel wall, but not in the channel direction, i.e. not in the direction of the end face, can be inserted into the channel section. Finally, the non-cured lacquer is rinsed out of the already etched channel section. Alternatively, a lacquer-impregnated sponge or felt body on a probe can be inserted into the channel section, and then, e.g. by the use of a spacer mandrel or the like, is prevented from wetting the end face of the channel, i.e. the future etching front.

As has been described further above, the workpiece can be formed from fused silica, in particular from titanium-doped fused silica, or from a glass ceramic. As has been described in the introduction, particularly in the case of fused silica, the etching selectivity vis-à-vis other materials such as e.g. sapphire is comparatively low, and so it is desirable to increase the etching selectivity for this material. Fused silica, in particular titanium-doped fused silica, is however often used for the production of substrates for reflective optical elements. In the case of a glass ceramic, too, the method described further above can optionally be advantageously employed.

In the case of selective laser-induced etching, the laser radiation that is focused into the volume of the workpiece generally has a wavelength of approximately 1 μm or—with the use of frequency-doubled light—of the order of magnitude of approximately 500 nm. None of these wavelengths makes it possible to bring about incoupling into the IR absorption bands of fused silica or of titanium-doped fused silica or to bring about excitation into the conduction band of fused silica in a two-photon process. Therefore, the use of laser radiation having a wavelength of the order of magnitude of approximately 1 μm is in any case highly inefficient for these materials since the light is not absorbed linearly, but rather only in a multiphoton process.

In the case of selective laser-induced etching for at least partly forming the hollow structure, it is therefore advantageous—irrespective of whether or not the increase in the etching selectivity described further above is realized—if the pulsed laser radiation is focused into the irradiation volume at at least one wavelength which is absorbed in an absorption band of the material of the workpiece in a wavelength range of between 2500 nm and 3120 nm, between 2150 nm and 2230 nm, or between 1380 nm and 1400 nm. The material of the workpiece can be in particular fused silica or titanium-doped fused silica.

It is appropriate to use for both materials, i.e. for fused silica and for titanium-doped fused silica, laser radiation which can be absorbed in a two-photon process at approximately 2500 nm, 2230 nm or 1380 nm, i.e. has for example double the wavelength of one of said absorption bands or wavelengths. Alternatively, it is also possible to use laser radiation with different wavelengths, provided that the added photon energy corresponds to that of one of the absorption bands described above.

The absorption bands of hydroxyl groups in fused silica are evident from the transmission curve of fused silica as a function of wavelength, which can be retrieved for example at “https://www.heraeus.com/media/media/hqs/doc_hqs/products_and_solutions_8/optics/Daten_und_Eigenschaften_Quarzglas_fuer_die_Optik_DE.pdf”. The absorption bands of titanium-doped fused silica or the transmission as a function of wavelength can be retrieved for example at “www.pgo-online.com/de/kurven/ule_tkurve.html”. The intensity used for an OH-poor glass must be higher than that used for an OH-rich glass.

In the case of a workpiece composed of fused silica, for the purpose of at least partly forming the hollow structure, the pulsed laser radiation can be focused into the irradiation volume at at least one wavelength which is at 351 nm or less, preferably at 308 nm or less, particularly preferably at 275 nm or less, in particular at 266 nm or less. For absorption into the conduction band, in the case of fused silica it is appropriate to use light or laser radiation of an excimer laser at wavelengths of 351 nm, 308 nm, 248 nm or 193 nm or frequency-multiplied light of a solid-state laser having a wavelength which is at 266 nm. A laser which emits at a wavelength of approximately 275 nm can also be used for this purpose.

In the case of a workpiece composed of titanium-doped fused silica, when at least partly forming the hollow structure, the pulsed laser radiation can be focused into the irradiation volume at at least one wavelength which is between 260 nm and 520 nm. For absorption into the conduction band, in the case of titanium-doped fused silica it has proved to be advantageous to use laser radiation of between 260 nm and 520 nm for the focusing into the irradiation volume.

When at least partly forming the hollow structure by selective laser-induced etching described further above, pulsed (spatially and temporally) coherent laser radiation, in particular pulsed coherent excimer laser radiation, can be focused into the irradiation volume. It has been found that during the irradiation of fused silica or titanium-doped fused silica with coherent laser radiation, typically at wavelengths in the UV wavelength range, firstly light guide structures and then small channels (microchannels) form, while the formation following the breaking of the spatial coherence of the laser light occurs only after a significant delay. It may be expected that the light guide structures already have a high density of broken bonds and are thus readily etchable. The (micro)channels offer the etching solution an increased surface area for the etching process in any case.

Therefore, in the case described here, it is proposed to use, instead of IR radiation with pulse durations in the ps or fs range, for selective laser-induced etching, excimer laser radiation or frequency-multiplied solid-state laser radiation in the UV wavelength range at wavelengths of approximately 351 nm or less, for example at 275 nm or less. The pulse durations of the pulsed laser radiation are generally in the low ns or in the high ps range. Preferably, in this case, directly the collimated and unfiltered laser beam generated by a laser source is focused into the irradiation volume, more precisely into a focus volume within the irradiation volume, in order to prevent the laser beam from losing its spatial and temporal coherence.

When at least partly forming the hollow structure, it is possible to carry out the selective etching in the irradiation volume with a reactive plasma, wherein preferably the reactive plasma is fed to an end face of a channel section formed during the selective etching in the irradiation volume. In this case, too, the end face of the channel section formed in the irradiation volume can be etched with a higher etching rate than a channel wall of the channel section.

The reactive plasma or the reactive plasma species can be for example reactive oxygen species, e.g. oxygen radicals, but also other reactive species, e.g. reactive hydrogen species. For etching with the aid of the reactive plasma, a comparatively small plasma source on a probe or the like can be guided along the pre-irradiated channels, more precisely along an already etched channel section, as far as the end face of the channel section in order to expose the end face of the channel section locally to the reactive plasma. In this case, the plasma source can be periodically inserted into the channel section and periodically removed again and the waste material can be purged. Alternatively, continuous or quasi-continuous purging can also be employed. The purging without a probe introduced into the channel section is preferably carried out using a liquid solution or using a liquid jet, and the purging with a probe inserted is preferably carried out using a gas jet.

Since the smallest plasma sources currently have a diameter of approximately 10 mm, it is not possible to produce channels having significantly smaller diameters by inserting a probe into a respective channel. It is instead necessary in this case to use a stronger plasma source that remains in the vicinity of the entrance of the channel (outside the workpiece). In this case, the etching front or the cooling channel can be tracked by the plasma by virtue of the plasma being guided via a feed into the vicinity of the end face of the cooling channel or into the vicinity of the end face of the already etched channel section. As feed for the plasma or the plasma species, a small tube or a hose can be used, for example, the free end of which is situated in the vicinity of the etching front at the end face of the channel. The hose can have ring-shaped or spiral reinforcing elements in order to enable its cross-section to be stabilized in conjunction with good flexibility. Since losses of reactive atoms or species take place in this case, it is necessary for such an external plasma source to be designed to be correspondingly more powerful. The feed e.g. in the form of a small tube or the like may need to be regularly exchanged in this case or can be formed from an etching-resistant material or can be provided with an etching-resistant inner coating or inner lining.

As described in WO2021/115643 A1 cited further above, it is possible, in order to increase the etching selectivity during the etching process, to irradiate the etching front, i.e. the region in which the etching solution is at present attacking the material of the substrate, with the laser radiation used for the modification of the material or with laser radiation at other wavelengths. In this case, in particular, the actual damage or modification of the material during selective laser-induced etching can only be effected in the etching bath. In the case, too, of most of the other possibilities described further above, the formation of the irradiation volume by focusing pulsed laser radiation and the selective etching of the workpiece in the irradiation volume can be carried out not just temporally successively, but optionally temporally in parallel. In the latter case, it is necessary for the etching apparatus to comprise an exposure system that enables the pulsed laser radiation to be focused in the irradiation volume when the workpiece is arranged in the etching bath or in an etching solution. The etching bath or the etching solution can be a (slightly) acidic, a substantially neutral or a basic etching solution. The advantage of a substantially neutral etching solution is that it minimizes the roughening. Neutral or slightly acidic and in particular demineralized or distilled water can also be used as an etching solution; also cf. the article “Water-assisted femtosecond laser ablation for fabricating three-dimensional microfluidic chips”, Yan Li, Shiliang Qu, Current Applied Physics, Vol. 13, Issue 7, 2013, pages 1292-1295.

A further aspect of the invention relates to a mirror, in particular an EUV mirror, comprising: a workpiece in the form of a substrate configured as described further above, and a reflective coating for reflecting radiation, in particular for reflecting EUV radiation, the coating being applied to a surface of the substrate. The reflective coating, for reflecting radiation, can comprise a plurality of pairs of layers composed of materials each having a different real part of the refractive index.

A further aspect of the invention relates to a lithography system, in particular an EUV lithography system, comprising: at least one workpiece as described further above, and/or at least one mirror, in particular an EUV mirror, as described further above, and a temperature control device, in particular a cooling device, which is configured to cause a temperature control fluid, in particular a cooling fluid, to flow through the at least one hollow structure. The workpiece can be an optical component or a non-optical, for example mechanical, component, for example a wafer chuck, a wafer table, or a structural component of the lithography system, e.g. in the form of a mount, in particular in the form of a frame for mounting optical elements, a frame for mounting sensors, or in the form of a carrying frame, such as are used in EUV lithography systems, specifically in EUV lithography apparatuses.

The temperature control device can serve as a cooling device and can be configured for example to allow a cooling medium in the form of a cooling fluid, for example a cooling liquid, for example in the form of cooling water, to flow through the hollow structure. For this purpose, the temperature control or the cooling device can optionally have a pump and also suitable feed and removal lines. The temperature control device can also serve as a heating device for heating the workpiece or the substrate. In this case, a temperature control fluid in the form of a heating fluid, which generally likewise is a liquid, is fed to the hollow structure in the form of the channel. It is also possible for the temperature control device to be configured to both heat and cool the mirror. Water is preferably used as the temperature control fluid to be caused to flow through the hollow structure in the form of the channel—both in the case of cooling and in the case of heating.

The hollow structure of the workpiece or of the substrate has an inlet opening for the entrance of the fluid and an outlet opening for the exit of the fluid. The inlet opening and the outlet opening can be connected to a port of a fluid feed line and a fluid removal line, respectively, in order to connect the hollow structure to the temperature control device. For the case where a plurality of fluidically separated hollow structures or channels run in the workpiece or in the substrate, these are connected to the temperature control device through separate inlet and outlet openings.

Further features and advantages of the invention are evident from the following description of exemplary embodiments, with reference to the figures of the drawing, which show details salient to the invention, and from the claims. The individual features can each be realized individually by themselves or as a plurality in any desired combination in variants of the invention.

### BRIEF DESCRIPTION OF THE DRAWINGS

Exemplary embodiments are illustrated in the schematic drawing and are explained in the following description. In the Figures:

FIG. 1 schematically shows a meridional section of a projection exposure apparatus for EUV projection lithography,

FIGS. 2A and 2B show differently oriented plan views of schematic sectional illustrations of a mirror of the projection exposure apparatus from FIG. 1, comprising a hollow structure having a plurality of temperature control channels in the form of cooling channels, the end sections of which merge into distributor channels or into collector channels via rounded-off sections,

FIGS. 3A-3D show schematic illustrations of a rounded-off section between a distributor channel and an end section of a cooling channel with identical flow diameters but four respectively differing radii of curvature in the four FIGS. 3A-3D,

FIGS. 4A-4D show schematic illustrations of a rounded-off section between a collector channel and an end section of a cooling channel with identical flow diameters but four respectively differing radii of curvature in the four FIGS. 4A-4D,

FIG. 5A shows a perspective illustration of a substrate for an EUV mirror comprising a hollow structure analogous to FIGS. 2A and 2B, in which the end sections of the cooling channels are oriented at an obtuse angle with respect to the distributor channels or to the collector channels,

FIG. 5B shows a schematic illustration of a rounded-off section at the transition between an end section of a cooling channel and a distributor channel, and

FIGS. 6A-6D show differently oriented plan (FIG. 6A and FIG. 6D) and perspective (FIG. 6B and FIG. 6C) views of illustrations of a substrate for an EUV mirror with a hollow structure analogous to FIGS. 2A and 2B, in which the distributor channels and the collector channels are oriented at an obtuse angle with respect to an inlet channel and to an outlet channel, respectively, and merge into the inlet channel and into the outlet channel at a rounded-off section,

FIGS. 6E and 6F show differently oriented perspective (FIG. 6E) and plan (FIG. 6F) views of illustrations of a multipartite substrate for an EUV mirror comprising a hollow structure configured in a manner similar to that in FIGS. 6A-D,

FIGS. 7A and 7B show schematic illustrations of two steps of a method for the selective laser-induced etching of a channel into a substrate,

FIG. 8 shows a schematic illustration of a channel section formed during the selective laser-induced etching with an end face that is at an increased temperature relative to the rest of the substrate,

FIG. 9 shows a schematic illustration analogous to FIG. 8 in which, in order to increase the etching rate, the end face of the channel section is exposed to an increased throughput of an etching solution,

FIG. 10 shows a schematic illustration analogous to FIG. 8 in which, in order to increase the etching rate, the end face of the channel section is mechanically freed of etched particles,

FIG. 11 shows a schematic illustration analogous to FIG. 8 in which, in order to increase the etching selectivity, the end face of the channel section is exposed to ultrasonic waves,

FIG. 12 shows a schematic illustration analogous to FIG. 8 in which a channel wall of the channel section is sealed with a protective lacquer,

FIG. 13 shows a schematic illustration analogous to FIG. 8 in which the etching is effected with a reactive plasma that is fed to the end face of the channel section,

FIGS. 14A-14C show schematic illustrations of a channel section formed during the selective laser-induced etching with an end face to which a purging fluid is fed via a flexible hose (outfitted either without (FIG. 14A) or with (FIG. 14B) a nozzle (FIG. 14C) mounted at the exit-side end of the hose,

FIGS. 15A-15C show schematic illustrations of a flexible hose in the course of insertion (FIG. 15A and FIG. 15B), into a channel section using a rigid guide element and a tracking device (FIG. 15B) comprising a drive roller and a guide roller (FIG. 15B, FIG. 15C),

FIGS. 16A-16D show schematic illustrations of the insertion and the tracking of the flexible hose via a tracking device with two chucks, at sequential stages (FIG. 16A . . . FIG. 16D) of the insertion process,

FIGS. 17A and 17B show schematic illustrations, in micrograph and table form, respectively, of a surface of a wall of a channel which was produced in the manner described further above in association with FIGS. 7A and 7B,

FIGS. 18A and 18B show schematic illustrations, in micrograph and table form, respectively, analogous to FIGS. 17A and 17B on a different scale, and

FIG. 19 shows a further schematic illustration of a surface of a wall of a channel which was produced in the manner described further above in association with FIGS. 7A and 7B.

### DETAILED DESCRIPTION

In the following description of the drawings, identical reference symbols are used for identical or functionally identical components.

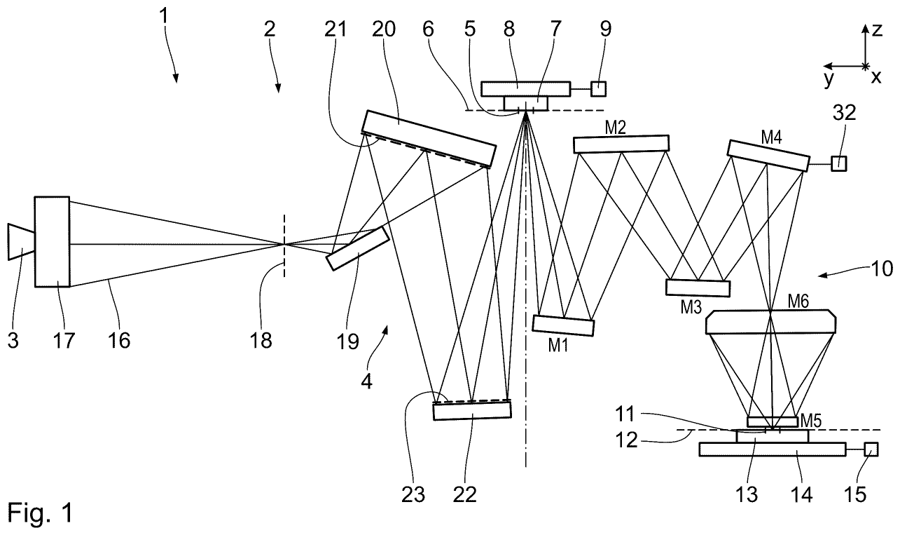

The salient components of an optical arrangement for EUV lithography in the form of a microlithographic projection exposure apparatus 1 are described by way of example below with reference to FIG. 1. The description of the basic setup of the projection exposure apparatus 1 and the components thereof should not be considered here to be restrictive.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable through a reticle displacement drive 9, in particular in a scanning direction.

For explanation purposes, a Cartesian xyz-coordinate system is depicted in FIG. 1. The x-direction runs perpendicularly into the plane of the drawing. The y-direction runs horizontally and the z-direction runs vertically. The scanning direction runs along the y-direction in FIG. 1. The z-direction runs perpendicularly to the object plane 6.

The projection exposure apparatus 1 comprises a projection system 10. The projection system 10 is used to image the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable with a wafer displacement drive 15, in particular along the y-direction. The displacement, firstly, of the reticle 7 with the reticle displacement drive 9 and, secondly, of the wafer 13 with the wafer displacement drive 15 can be implemented so as to be synchronized with one another.

The radiation source 3 is an EUV radiation source. The radiation source 3 emits, in particular, EUV radiation 16, which is also referred to below as used radiation, illumination radiation or illumination light. In particular, the used radiation has a wavelength in the range of between 5 nm and 30 nm. The radiation source 3 can be a plasma source, for example an LPP (Laser Produced Plasma) source or a DPP (Gas Discharge Produced Plasma) source. It can also be a synchrotron-based radiation source. The radiation source 3 can be a free electron laser.

The illumination radiation 16 emanating from the radiation source 3 is focused by a collector mirror 17. The collector mirror 17 can be a collector mirror with one or more ellipsoidal and/or hyperboloidal reflection surfaces. The illumination radiation 16 can be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 can be structured and/or coated, firstly, for optimizing its reflectivity for the used radiation and, secondly, for suppressing extraneous light.

Downstream of the collector mirror 17, the illumination radiation 16 propagates through an intermediate focus in an intermediate focal plane 18. The intermediate focal plane 18 can constitute a separation between a radiation source module, comprising the radiation source 3 and the collector mirror 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. Alternatively or additionally, the deflection mirror 19 can be embodied as a spectral filter separating a used light wavelength of the illumination radiation 16 from extraneous light having a wavelength that deviates therefrom. The first facet mirror 20 comprises a multiplicity of individual first facets 21, which are also referred to below as field facets. FIG. 1 illustrates only some of these facets 21 by way of example. In the beam path of the illumination optical unit 4, a second facet mirror 22 is disposed downstream of the first facet mirror 20. The second facet mirror 22 comprises a plurality of second facets 23.

The illumination optical unit 4 consequently forms a doubly faceted system. This fundamental principle is also referred to as a fly's eye integrator. With the aid of the second facet mirror 22, the individual first facets 21 are imaged into the object field 5. The second facet mirror 22 is the last beam-shaping mirror or else indeed the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection system 10 is a doubly obscured optical unit. The projection optical unit 10 has an image-side numerical aperture which is greater than 0.4 or 0.5 and which can also be greater than 0.6 and which can be for example 0.7 or 0.75.

Just like the mirrors of the illumination optical unit 4, the mirrors Mi can have a highly reflective coating for the illumination radiation 16.

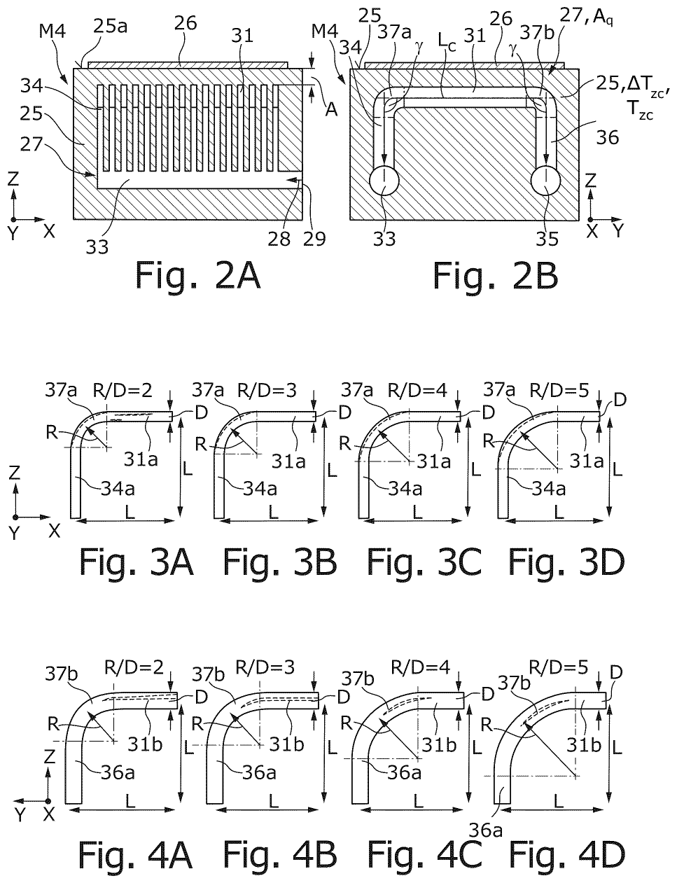

FIGS. 2A and 2B show one example of an embodiment of the mirror M4 of the projection system 10, which mirror comprises a monolithic workpiece in the form of a substrate 25 in the example shown. In the example shown, the material of the substrate 25 is titanium-doped fused silica with a very small coefficient of thermal expansion. The substrate 25 can also be formed from a different material having a coefficient of thermal expansion that is as small as possible, for example from a glass ceramic. The zero crossing temperature TZC of the substrate 25 is between 0° C. and 100° C., typically between 19° C. and 40° C., in particular between 19° C. and 32° C. The zero crossing temperature TZC is substantially constant throughout the volume of the substrate 25 and has a spatial variation that is less than 3 K, less than 2 K, less than 1 K or less than 0.1 K, with the spatial variation denoting the difference between maximum and minimum zero crossing temperature TZC.

A reflective coating 26 is applied to a surface 25a of the substrate 25 for reflection of EUV radiation 16, which is illustrated in FIG. 1. A portion of the surface 25a which is located within the reflective coating 26 is struck by the EUV radiation 16 of the projection system 10 and forms an optically used portion of the reflective coating 26 not depicted here. To reflect the EUV radiation 16, the reflective coating 26 can have, for example, a plurality of layer pairs made of materials with in each case a different real part of the refractive index, the layer pairs possibly being formed from Si and Mo, for example, in the case of a wavelength of the EUV radiation 16 of 13.5 nm.

The substrate 25 has a hollow structure 27 through which a fluid 28 can flow, the latter being water in the example shown. The fluid 28 indicated by an arrow in FIG. 2A enters into the substrate 25 via an entrance opening 29 on a side surface in order to flow through a plurality of temperature control channels in the form of cooling channels 31, which form a part of the hollow structure 27, in order thus to cool in particular the surface 25a of the substrate 25 to which the reflective coating 26 is applied and whose temperature is to be regulated.

To feed the fluid 28 to the inlet opening 29 and to remove the fluid 28 from an outlet opening, not depicted in FIGS. 2A and 2B, the projection exposure apparatus 1 comprises a temperature control device 32 configured in the form of a cooling device, which is illustrated schematically in FIG. 1. In the example shown, the cooling device 32 serves to feed a coolant in the form of cooling water 28 to the mirror M4, and for this purpose comprises a feed line, not depicted, which is connected to the coolant inlet 29 in fluid-tight fashion. The cooling device 32 also comprises a removal line, not depicted, in order to remove the cooling water 28 from the coolant outlet, not depicted. The other mirrors M1-M3, M5, M6 of the projection system 10 can also have a hollow structure 27 which, for cooling purposes, are connected to the cooling device 32 or optionally to further cooling devices provided for this purpose. Instead of a cooling device 32, a temperature control device can also be provided in the projection exposure apparatus 1, that is to say a device used to cool and/or heat the mirrors M1-M6. A suitable temperature control fluid 28 can be used for heating, for example water which is heated to a desired temperature before being fed to the hollow structure 27.

As is evident from FIG. 2A, the fluid 28 enters an inlet channel 33 of the hollow structure 27 via the inlet opening 29, this inlet channel forming a fluid distributor and a plurality of distributor channels 34 branching off from the inlet channel, which distributor channels are each connected to one of the plurality of temperature control channels, referred to as cooling channels 31 hereinafter. The cooling channels 31 are arranged spaced apart at a distance A of approximately 5 mm from the surface 25a of the substrate 25, which is planar in the example shown, and extend parallel to the surface 25a, that is to say parallel to an XY-plane of an XYZ-coordinate system. The cooling channels 31 run in a straight line, are aligned parallel and extend in the longitudinal direction, which corresponds to the Y-direction, over almost the entire portion of the surface 25a of the substrate 25 that is covered by the coating 26; cf. FIG. 2B. From the cooling channels 31, the fluid 28 flows via a plurality of collector channels 36 to a fluid collector, which is configured as an outlet channel 35 in the example shown in FIG. 2B. The outlet channel 35 has the outlet opening described further above, and not depicted in FIGS. 2A and 2B, via which the fluid 28 emerges from the hollow structure 27 of the substrate 25.

As is evident from FIG. 2B, the hollow structure 27 has a first rounded-off section 37a, at which a respective distributor channel 34 merges into a cooling channel 31. Accordingly, the hollow structure 27 also has a second rounded-off section 37b, at which a respective cooling channel 31 merges into a collector channel 36. In the example shown, the cooling channels 31 run in a straight line in the horizontal direction, which corresponds to the Y-direction, and the distributor channels 34 and the collector channels 36 run in a straight line in the vertical direction, which corresponds to the Z-direction. Accordingly, the longitudinal axes of the cooling channels 31 are oriented at an angle γ of 90° with respect to the distributor channels 34 and to the collector channels 36. The rounded-off section 37a,b serves to generate a flow guidance that is as streamlined as possible in order thus to avoid or at least significantly reduce the occurrence of turbulence, as would occur in the case of a non-rounded-off, “corner-like” 90° bend. The reduction of turbulence has as a consequence a reduction in the flow-induced vibrations of the reflective optical element M4.

The distributor channel 34 shown in FIGS. 2A and 2B, the cooling channel 31 adjoining this distributor channel, and the collector channel 36 adjoining the cooling channel 31 form three sections of a continuous, curved channel 31, 34, 36, the length LC of which is approximately 10 cm in the example shown. However, the length LC of the channel 31, 34, 36 can also be greater and can be approximately 15 cm or more, approximately 20 cm, or more than approximately 20 cm. The diameter of the channel 31, 34, 36 can be for example between approximately 1 mm and approximately 20 mm, in particular between approximately 1 mm and approximately 5 mm. In principle, the cross-sectional area Aq of the channel 31, 34, 36 should vary over the length LC of the channel 31, 34, 36 by not more than +/−20% or by not more than +/−10%. In the example shown, the channel 31, 34, 36 has a cross-sectional area Aq that varies over the length LC of the channel 31, 34, 36 by not more than +/−2%.

For an optimized flow guidance at the 90° bend, it is advantageous if the rounded-off section 37a,b has a constant radius of curvature R, as illustrated in FIGS. 3A-3D and in FIGS. 4A-4D. An important parameter for an optimal flow guidance is represented by the ratio between the radius of curvature R of the rounded-off section 37a, 37b and the flow diameter D.

FIGS. 3A-3D show the first rounded-off section 37a, at which an end section 31a of a respective cooling channel 31 and a distributor channel section 34a adjoining the end section 31a adjoin one another, in the case of four different ratios between the radius of curvature R of the rounded-off section 37a and the diameter D of the rounded-off section 37a. In this case, the radius of curvature R is measured in the center of the rounded-off section 37a, as illustrated in FIGS. 3A-3D. The diameter D of the rounded-off section 37a is 5 mm in all four examples shown. The diameter D of the rounded-off section 37a in this case corresponds to the diameter D of the distributor channel 34 and the diameter D of the cooling channel 31. The length L is approximately 50 mm in the illustrations of FIGS. 3A-3D. As is evident from FIGS. 3A-3D, the R/D ratio is R/D=2, R/D=3, R/D=4 and R/D=5, respectively, in the four examples shown.

In a manner analogous to FIGS. 3A-3D, FIGS. 4A-4D show the second rounded-off section 37b, at which an end section 31b of a respective cooling channel 31 and a collector channel section 36a adjoining the end section 31b merge into one another. The diameter D of the rounded-off section 37b is 10 mm in FIGS. 4A-4D. In the illustrations of FIGS. 4A-4D, the length L is approximately 60 mm. In the illustration of FIGS. 4A-4D, the R/D ratio is also R/D=2, R/D=3, R/D=4 and R/D=5, respectively, in the four examples shown. The diameter D of a respective rounded-off section 37a, 37b is typically between 2 mm and 20 mm, ideally between 2 mm and 12 mm.

As has been described further above, there is an optimum ratio between the radius of curvature R and the diameter D of the respective rounded-off section 37a, 37b, at which the centrifugal force acts such that the pressure of the flowing fluid 28 at the outer side of the rounded-off section 37a, 37b increases only minimally in comparison with the inner side of the rounded-off section 37a,b and this allows a reduction in the boundary layer separation to be attained upstream and downstream of the rounded-off section 37a,b. FIGS. 3A-3D and FIGS. 4A-4D illustrate the contours of regions in which the turbulent kinetic energy of the flowing fluid 28 exceeds a specified value. In this case, the assumption was made that the fluid 28 flows from the distributor channel section 34a or from the collector channel section 36a into the respective end section 31a or 31b of the cooling channel 31.

For this purpose, a ratio between the radius of curvature R of the rounded-off section 37a, 37b and the diameter D of the rounded-off section 37a, 37b of between 2 and 6, better between 2.5 and 5, ideally between 2.5 and 3.5, has been found to be particularly advantageous. There can typically be no significant reduction in the boundary layer separation in the case of an R/D ratio of less than 2. An optimal value for the R/D ratio is typically between 2.5 and 3.5, but the optimal value may optionally also be outside this value range. There is typically a deterioration in the flow behavior in the case of an R/D ratio of more than 6.0.

In practice, the rounded-off section 37a,b cannot be produced with the aid of conventional processing methods in a monolithic substrate 25, as described further above. In the example shown, only the inlet channel 33 and the outlet channel 35 are produced by a conventional processing method, to be precise by virtue of a respective drilled hole being introduced into the substrate 25. By contrast, the distributor channels 34, the cooling channels 31 and the collector channels 36 were produced by selective laser-induced etching of the material of the substrate 25, as will be described in more detail further below. In principle, the inlet channel 33 and the outlet channel 35 can also be produced by selective laser-induced etching.

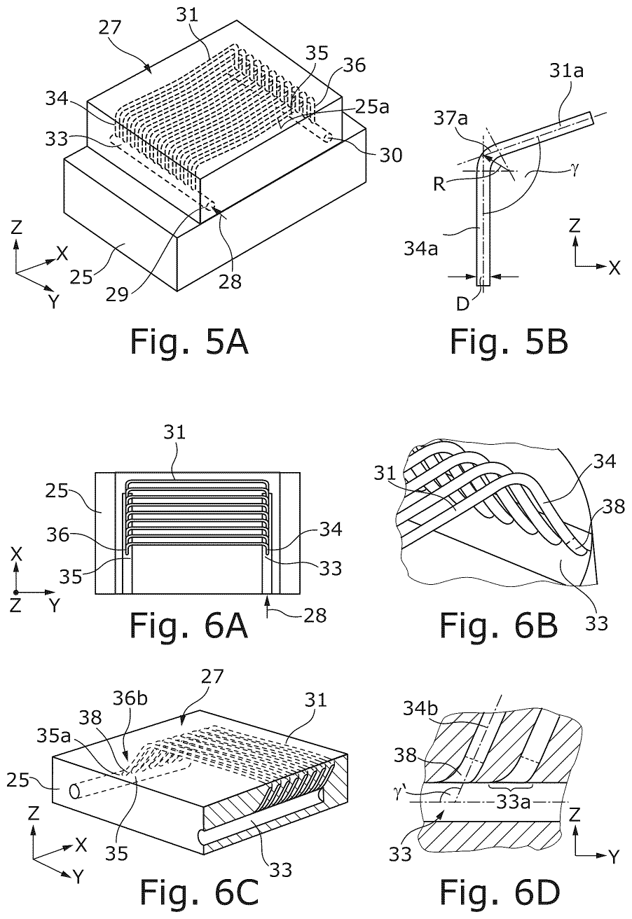

In the case of the hollow structure 27 described further above, only the two sections 37a, 37b are rounded-off, while the distributor channels 34, the collector channels 36 and the cooling channels 31 run in a straight line. However, more complex hollow structures 27 can also be produced with the aid of selective laser-induced etching described further below. FIGS. 5a,b show one example of such a hollow structure 27 in a substrate 25, which substantially corresponds to the hollow structure 27 illustrated in FIGS. 2A and 2B. The hollow structure 27 differs from the hollow structure 27 in FIGS. 2A and 2B in that the cooling channels 31 have a slight curvature, which follows the curvature of the surface 25a which is concavely curved in the example shown. In the example shown in FIG. 5B, an end section 31a of a respective cooling channel 31 adjacent to the distributor channel 34 is oriented at an angle γ of approximately 115°. Despite the fact that the cooling channel 31 has a curvature running in the ZX-plane, it is possible to define a longitudinal axis, which defines the angle γ, for the end section 31a adjoining the rounded-off section 31a. It is understood that the second rounded-off section 37b, which is not depicted in FIGS. 5A and 5B, is configured in a manner corresponding to the first section 37a. The R/D ratio between the radius of curvature R and the diameter D of the respective rounded-off sections 37a,b is typically in the value range described further above.

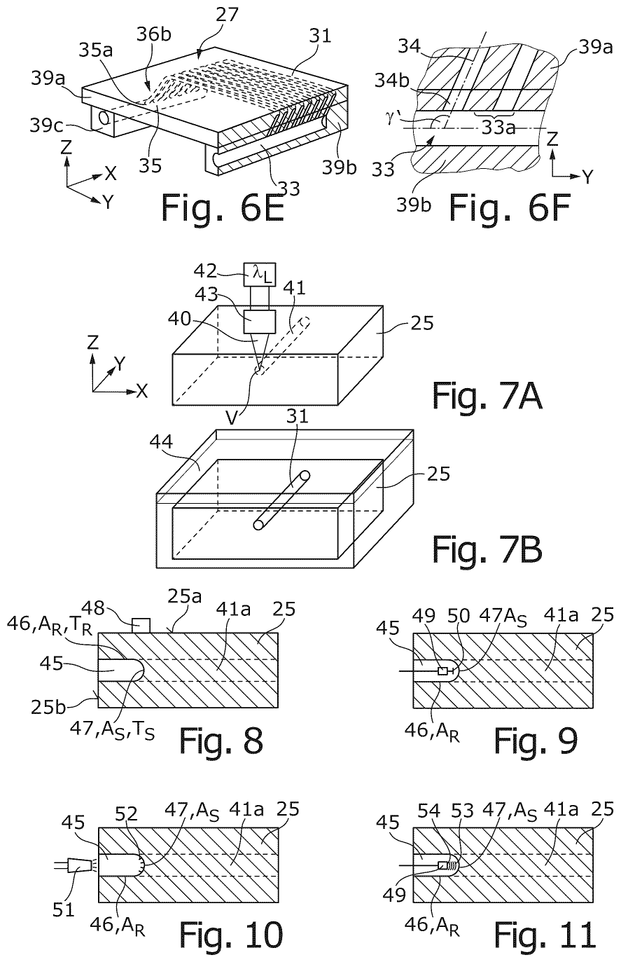

In the case of the substrate 25 shown in FIGS. 6A-6F, the hollow structure 27 is configured substantially like the hollow structure 27 shown in FIGS. 2A and 2B, but differs from the latter in that the distributor channels 34 and the collector channels 36 do not run in the vertical direction but rather are oriented at an angle of approximately 25° with respect to the thickness direction Z of the substrate 25. Like the hollow structure 27 shown in FIGS. 2A and 2B, the hollow structure 27 shown in FIGS. 6A-6D has two rounded-off sections 37a, 37b, not depicted, between the respective distributor channels 34 or collector channels 36 and the cooling channels 31. The angle γ between the distributor channels 34 or the collector channels 36 and the cooling channels 31 is also 90° in this case, but it runs in a plane that is inclined by approximately 25° with respect to the thickness direction Z, as is evident from FIG. 6D, which shows an angle γ′ of approximately 115° between the longitudinal axis of the inlet channel 33 and a respective distributor channel 34.

The hollow structure 27 shown in FIGS. 6A-6D has rounded-off sections 38, at which a merging section 34b of a respective distributor channel 34 transitions into the inlet channel 33, more precisely into a branching section 33a of the inlet channel 33, or at which a merging section 36b of a respective collector channel 36 transitions into a branching section 35a of the outlet channel 35. In the example shown, the respective rounded-off section 38 does not have a constant diameter or flow cross-section; instead, the flow cross-section reduces starting from the branching section 33a. The rounded-off section 38 also does not have a constant radius of curvature R, as is the case for the two curved sections 37a,b which run between the respective distributor channels 34 or collector channels 36 and a respective cooling channel 31. Accordingly, it is not possible to specify an optimized ratio of radius of curvature R to diameter D. The rounded-off section 38 can also be produced with the aid of the selective laser-induced etching method described further below.

The hollow structure 27 illustrated in FIGS. 6E and 6F differs from the hollow structure 27 illustrated in FIGS. 6A-6D in that the substrate is not configured in monolithic fashion, but rather is composed of three substrate parts 39a, 39b, 39c consisting of titanium-doped fused silica. The second substrate part 39b and the third substrate part 39d are mounted on the underside of the first substrate part 39a, more precisely are permanently connected to the underside of the first substrate part 39a. In the example shown, the permanent connection is produced by thermal bonding, in the case of which the planar underside of the first substrate part 39a is connected to the planar top side of the second substrate part 39a and to the planar top side of the third substrate part 39b in the bare state. Optionally, the respectively two substrate parts 39a, 39b; 39a, 39c can be connected to one another by wringing prior to the bonding.

The cooling channels 31, the respective rounded-off sections 37a, 37b and the distributor channels 34 and collector channels 36 adjacent thereto, with the exception of the respective merging sections 34b, 36b, run in the first substrate part 39a. The merging sections 34b of the distributor channels 34 run in the second substrate part 39b, and the merging sections 36b of the collector channels 36 run in the third substrate part 39c. In addition, the inlet channel 33 of the hollow structure 27 runs in the second substrate part 39b, and the outlet channel 35 of the hollow structure 27 runs in the third substrate part 39c. Both the inlet channel 33 and the outlet channel 35 are introduced into the second and third substrate parts 39a, 39b, respectively, by drilling. The merging sections 34b of the distributor channels 34 are drilled into the second substrate part 39b proceeding from the top side thereof before the second substrate part is connected to the underside of the first substrate part 39a. The merging sections 36b of the collector channels 36 are correspondingly drilled into the third substrate part 39c proceeding from the top side thereof. As is evident in FIG. 6F, no rounded-off section is therefore formed at the respective merging sections 34b, 36b.

As is likewise evident in FIG. 6F, the respective distributor channels 34 formed in the first substrate part 39a are directly adjacent to the respective merging section 34b. The distributor channels 34 and the collector channels 36 are likewise formed for the most part by a drilled hole being produced proceeding from the underside of the first substrate part 39a. Only the rounded-off sections 37a,b and the cooling channels 31 are produced by selective laser-induced etching in the first substrate part 39a. For this purpose, the first substrate part 39a with the respectively predrilled distributor channels 34 and collector channels 36 is dipped into an etching solution, as described in more detail further below. The bonding of the second and third substrate parts 39b,c is typically carried out after the selective laser-induced etching of the first substrate part 39a. In principle, however, it is also possible for the selective laser-induced etching not to be carried out until after the permanent connection or bonding of the three substrate parts 39a-c.

It is understood that the hollow structure 27 having the at least one rounded-off section 37a,b, 38 is not restricted to the examples described further above, rather that, in principle, other, more complex hollow structures 27 having one or more sections of this type can also run in the substrate 25. Moreover, not only is it possible for the cooling channels 31 to have a curvature as described in association with FIGS. 5A and 5B, but it is also possible for the distributor channels 34 and the collector channels 36 to run in curved fashion.

FIGS. 7A and 7B show two method steps of a selective laser-induced etching method for forming a channel 31 in a substrate 25 for one of the six mirrors Mi of the projection optical unit 10 from FIG. 1. After the channel 31 has been formed, more precisely after a plurality of channels 31 have been formed, the highly reflective coating 26 discussed further above is applied to the substrate 25. In the example shown, the channel 31 is a passage channel that can be used as a cooling channel to allow a cooling medium, not depicted, typically a cooling liquid, e.g. in the form of water, to flow through the substrate 25. For forming the channel 31 in the substrate 25, in the method step shown in FIG. 7A, pulsed laser radiation, more precisely a pulsed laser beam 40, is focused into a contiguous irradiation volume 41 in the substrate 25. In this case, the laser beam 40 is generated by a laser source 42 and is incident with free-space propagation on a focusing optical unit 43, which can be a focusing lens element in the simplest case.

The substrate 25 is transparent to the wavelength λL of the laser beam 40 and thus enables the laser beam 40 to be focused on a focus volume V around a focus position of the laser beam 40. In this case, the pulse energy of a respective pulse of the pulsed laser beam 40 is typically absorbed by multiphoton processes only within the focus volume V. In the focus volume V, the optical and chemical properties of the transparent material of the substrate 25 are changed, without cracks or possibly with microcracks, such it is rendered selectively chemically etchable. By deflecting or moving the focus volume V in the substrate 25, for example with a microscanner system, not depicted, it is possible to modify contiguous regions in the substrate 25 which form a contiguous irradiation volume 41. In the example shown in FIG. 7A, the focus volume V for forming a rectilinear irradiation volume 41 is moved along the Y-axis of an XYZ-coordinate system.

Depending on the laser parameters used, the modification of the material of the substrate 25 can be microcracks or other damage at depth. The irradiation volume 41 modified by the pulsed laser beam 40 is subsequently removed via wet-chemical etching, as is illustrated in FIG. 7B. During wet-chemical etching, the substrate 25 is typically immersed for several weeks or months in an etching solution 44, which preferably (i.e. selectively) dissolves the modified material in the irradiation volume 41 from the substrate 25 until this material has been completely removed, resulting in the formation of the channel 31 in the substrate 25.

In selective laser-induced etching, the laser beam 40 usually in the form of ultrashort pulsed laser radiation (ps or fs pulses) is focused into the focus volume V. The laser wavelength λL can be in the IR wavelength range at approximately 1 μm, for example. In the present example, the material of the substrate 25 is titanium-doped fused silica. In the case of this material, it has proved to be advantageous if the pulsed laser beam 40 is focused into the irradiation volume 41 at at least one wavelength λL which is between 260 nm and 520 nm in order to absorb the laser radiation in the conduction band of the titanium-doped fused silica. For the case where the material of the substrate 25 is (undoped) fused silica, it is advantageous for the absorption in the conduction band if the wavelength λL of the laser beam 40 is in the UV wavelength range, specifically typically at less than 266 nm, e.g. at 248 nm or at 193 nm. In the latter case, the laser source 42 can be configured for example as an excimer laser or as a frequency-multiplied solid-state laser.

Specifically if the material of the substrate 25 is fused silica or titanium-doped fused silica, it has proved to be advantageous if the laser beam 40 in the focus volume V satisfies the coherence condition, i.e. if a coherent laser beam 40 is radiated into the irradiation volume 41, specifically for the following reason: It has been found that when fused silica is irradiated with coherent laser radiation, firstly light guide structures and then microchannels form, whereas with the use of non-coherent laser radiation, the formation of such structures and hence a corresponding material modification do not occur until significantly later. The use of a coherent laser beam 40 having wavelengths in the UV wavelength range, for example at wavelengths of 351 nm or less, 308 nm or less, 275 nm or less, or 266 nm or less, as is generated for example by an excimer laser or a frequency-multiplied solid-state laser, in combination with comparatively long pulse durations e.g. of the order of magnitude of approximately 100 picoseconds to 100 nanoseconds, as are generated by Q-switched solid-state lasers or gas discharge lasers/excimer lasers, has therefore proved to be advantageous for the selective laser-induced etching of fused silica or titanium-doped fused silica.

As an alternative or optionally in addition to the focusing of laser radiation at wavelengths in the UV wavelength range, particularly in the case of the two materials mentioned further above, i.e. in the case of fused silica or in the case of titanium-doped fused silica, the irradiation volume 41 in the substrate 25 can also be irradiated with a laser beam 40 which has (at least) a wavelength λ_{L} which is absorbed in an IR absorption band of the material of the substrate 25 in a wavelength range of between 2500 nm and 3120 nm, between 2150 nm and 2230 nm, or between 1380 nm and 1400 nm. For this purpose, the laser beam 40 can have e.g. double the wavelength λ_{L} of the wavelength ranges mentioned above, in order to be absorbed in the corresponding absorption band in a two-photon process. Alternatively, the laser source 42 can also generate laser radiation at different wavelengths λ_{L}, the added photon energy of which corresponds to one of the absorption bands mentioned above. For this purpose, the laser source 42 can optionally comprise two or more lasers.

It is understood that a single irradiation volume 41 is illustrated in FIGS. 7A and 7B merely in order to simplify the illustration, but that in principle two or more irradiation volumes 41 can be formed in the substrate 25 in order to form two or more channels 31 in the substrate 25. It is furthermore understood that a network of (cooling) channels connected to one another can also be formed in the substrate 25. In principle, curved channels 31 can also be formed by selective laser-induced etching, i.e. a respective channel 31 need not necessarily be configured in rectilinear fashion, as illustrated in FIGS. 7A and 7B. In principle, any desired hollow structures 27 can be produced by the scanning or the movement of the laser beam 40 in the volume of the substrate 25.

The channel 31 can be configured in particular as described in association with FIGS. 2A and 2B or FIGS. 5A and 5B and can adjoin a distributor channel 34 or a collector channel 36. In particular, a respective end section 31a, 31b of the channel 31 can merge into a respective distributor channel section 34a of the distributor channel 34 or into a respective collector channel section 36a of the collector channel 36 at a rounded-off section 37a,b.

The selective laser-induced etching method described further above is not restricted to the substrate 25 of a mirror for an EUV lithography apparatus 1, but rather can for example also be used for forming channels in a substrate 25 of a reflective or transmissive optical element for a DUV lithography system. The selective laser-induced etching method can also be used to form channels in other workpieces or components of a lithography system, for example in workpieces which are intended to serve as mounts for optical elements and be integrated into the components, e.g. in the form of actuators, sensors, etc., or for workpieces in the form of a wafer chuck or a wafer table whose temperature is intended to be regulated with the aid of the hollow structure or with the aid of channels 31.

As is evident in FIG. 8, during the wet-chemical etching step illustrated in FIG. 7B, the etching process takes place proceeding from the edge or from a lateral surface 25b of the substrate 25 into the irradiation volume 41, wherein the etching results in the formation of a channel section 45 which extends in the irradiation volume 41 proceeding from a channel entrance at the lateral surface 25b of the substrate 25 as far as an end face 47 of the channel section at which an etching front is formed. The etching front or the end face 47 of the already etched channel section 45 is adjacent to a not yet etched volume region 41a of the irradiation volume 41. As the duration of the etching process increases, further material is gradually ablated along the irradiation volume 41, i.e. the not yet etched volume region 41a of the irradiation volume 41 decreases until the channel 31 extends across the entire irradiation volume 41.

When etching materials such as fused silica, titanium-doped fused silica, specific glass ceramics, etc., the etching selectivity in the irradiation volume 41 is comparatively low in comparison with the surrounding, non-irradiated volume of the substrate 25 and may be merely of the order of magnitude of 1:500. This can have the effect that the channel 31 formed during etching, in the vicinity of the respective channel entrance at the surface 25a of the substrate 25, has a possibly significantly larger cross-sectional area than further inside the volume of the substrate 25. A cross-sectional area that is not constant over the length of the channel 31 is typically disadvantageous, however, e.g. with regard to vibrations attributable to the flow of the (generally liquid) cooling medium.

In order to produce a cross-sectional area of a respective channel 31 that is substantially constant over the length of the channel 31, it is advantageous if the end face 47 of the channel section 45 is etched with a higher etching rate AS than the respective (circumferential) channel wall 46 of the channel section 45 is etched (etching rate AR<AS). The etching selectivity can thereby be increased, i.e. more material is ablated in the direction of the still remaining irradiation volume 41a or in the direction of the later channel 31 than in the direction of the channel wall 46, i.e. transversely with respect to the direction of the channel 31, which, in the example shown, corresponds to the Y-direction of the XYZ-coordinate system shown in FIGS. 7A and 7B.

The etching rate AS at the end face of the channel section 45 is typically of the order of magnitude of approximately 100 μm/h to several mm/h. For increasing the etching rate AS at the end face 47 of the channel section 45 or the etching selectivity, i.e. reducing the ratio AR/AS between the etching rate AR at the channel wall 46 of the channel section 45 and the etching rate AS at the end face 47 of the channel section 45, in the material of the substrate 25 there are various possibilities, a number of which will be described in more detail below, which can be employed individually or in combination, for increasing the etching rate AS or for reducing the ratio AR/AS. An etching selectivity or a ratio AR/AS of more than 1:1500 or possibly of more than 1:2000 can be achieved hereby. In order to reduce the total processing time, the substrate 25 can additionally be irradiated simultaneously using a plurality of laser sources 42 in order to produce a plurality of channels 31 or a plurality of etching fronts simultaneously.

In the case of the example shown in FIG. 8, for the purpose of increasing the etching rate AS, a temperature TS is produced at the end face 47 of the channel section 45 which is at least 20 K, at least 40 K or ideally at least 60 K greater than a temperature TR at the channel wall 46 of the channel section 45. The temperature TR at the channel wall 46 in this case typically corresponds to the temperature of the etching solution 44 or of the substrate 25 with the exception of the end face 47 of the channel section or the etching front. The temperature TR of the etching solution 44 should be as low as possible, i.e. be ideally just above or optionally just below the freezing point of the etching solution 44. By contrast, the etching front at the end face 47 of the channel section 45 is kept at the highest possible temperature TS, which is ideally at least 60 K greater than the temperature TR at the channel wall 46.

In order to maintain the temperature TS at the end face 47 of the channel section 4 while the etching process progresses, the end face 47 of the channel section 45 is heated with the aid of a heating device 48, which is guided concomitantly with the end face 47 of the channel section 45 during the formation of the channel 31. The heating device 48 thus is kept at a constant distance from the end face 47 of the channel section 45 and makes it possible for the temperature TS at the end face 47 of the channel section 45 to be kept approximately constant.

In the example shown in FIG. 8, the heating device 48 is situated outside the channel section 45 and bears on the top side 25a of the substrate 25, which is that surface of the substrate 25 which is at the smallest distance from the channel 31. After the selective laser-induced etching, the reflective coating is applied to the top side 25a in order to form the mirror Mi. In the example shown in FIG. 8, the heating device 48 is concomitantly guided in the Y-direction along the top side 25a of the substrate 25 parallel to the channel 31 or to the etching front at the end face 47, for which purpose a suitable mechanical movement device can be provided in the etching apparatus illustrated in FIG. 7B.

In the example shown in FIG. 8, the heating device 48 is a resistance heater that is in direct contact with the surface 25a in order to transfer contact heat to the material of the substrate 25. However, the heating device 48 can also be a heating light source, for example an infrared light source, or a laser that focuses radiation onto the end face 47 of the channel section 45 and is concomitantly guided during the formation of the channel 31. It is alternatively also possible to guide or thread the heating device 48 (e.g. in the form of a resistance heater or a light source) through the channel section 45 and to keep the heating device 48 ideally at a constant distance from the etching front or the end face 47 of the channel section 45. In this case, the heating device 48 can be mounted on a suitable carrier element having a smaller dimensioning than the channel diameter.

Such a carrier element (probe) 49 which is inserted into the channel section 45 in order to increase the etching rate AS at the end face 47 of the channel section 45 is illustrated in FIG. 9. In the example shown, the probe 49 is inserted into the channel section 45 and is guided concomitantly with the end face 47 of the already formed channel section 45 during the formation of the channel 31. The probe 49 can carry for example a heating device 48 e.g. in the form of a resistance heater.

In the example shown in FIG. 9, however, the probe 49 is used to carry a swirling device 50 in the form of a propeller in order to increase the throughput of etching solution 44 at the end face 47 of the channel section 45 and to increase the etching rate AS at the end face 47 of the channel section 45 thereby. Instead of a propeller, a different kind of swirling device, for example a turbine or the like, can also be mounted on the probe 49. Moreover, it is not absolutely necessary for the end face 47 of the channel section 45 to be continuously tracked by the probe 49, rather the probe 49 can be (periodically) intermittently introduced into the channel section 45 and removed again therefrom.

In FIG. 10, for increasing the etching rate AS, the end face 47 of the channel section 45 is mechanically freed of initially etched particles 52 by a nozzle 51 being arranged permanently or intermittently in front of the channel entrance of the channel section 45. Alternatively, the nozzle 51 can be inserted into the channel section 45 permanently progressively or intermittently with the aid of a probe 49, as described in association with FIG. 9. As an alternative or in addition to the nozzle shown in FIG. 10, a probe 49 can also comprise a mechanical stirrer, a brush, or the like, which is positioned in the vicinity of the end face 47 of the channel section 45 or is guided concomitantly therewith in order to remove particles 52 etched free from the end face 47 of the already formed channel section 45.

In the example shown in FIG. 11, for increasing the etching selectivity, the end face 47 of the channel section 45 is exposed to ultrasonic waves 53. The ultrasonic waves 53 are generated by an ultrasound exciter 54, which, on a probe 49 as in FIG. 9, is inserted into the channel section 45 and is positioned in the vicinity of the end face 47 of the channel section 45. The effect of the ultrasonic waves can consist in detaching initially etched particles 52, in recirculating the etching solution 44 and/or in a heating effect on the etching front or on the end face 47 of the channel section 45. In order to generate the ultrasonic waves 53, in a manner similar to that in FIG. 8, the ultrasound exciter 54 can alternatively also be arranged outside the substrate 25, e.g. on the top side 25a thereof, and be guided concomitantly with the etching front.

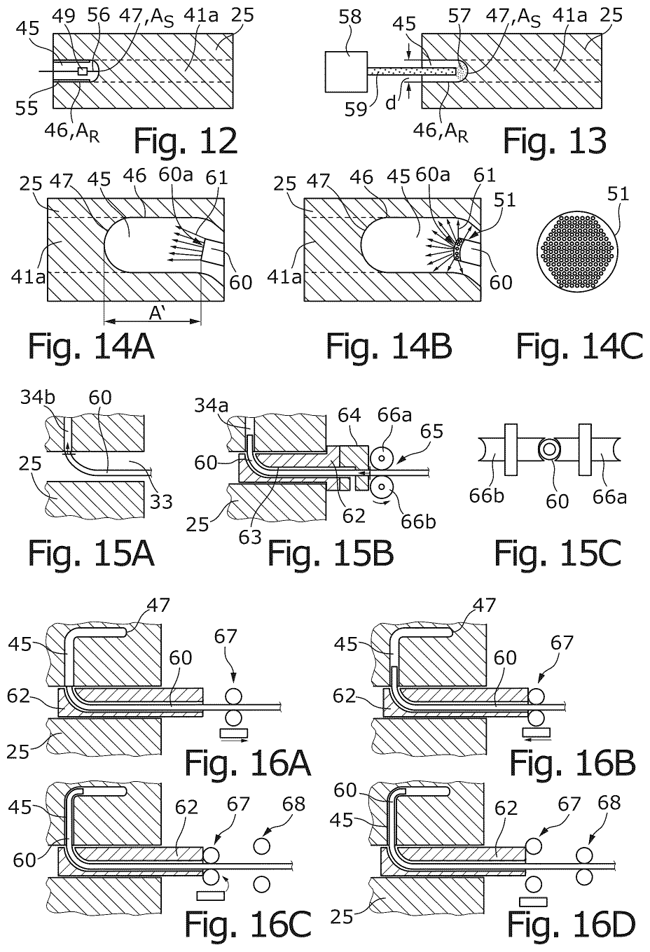

FIG. 12 shows a further possibility for increasing the etching rate AS at the end face 47 of the channel 31, which involves the channel wall 46 of the channel section 45 being sealed against etching or against the attack of the etching solution 44. For this purpose, in the example shown in FIG. 11, a protective lacquer 55 is applied to the channel wall 46. The protective lacquer 55 can be for example a polymer lacquer which withstands the attack of the etching solution. For applying the protective lacquer 55, it is necessary for the substrate 25 to be removed from the etching solution 44 and rinsed and dried. Removing and applying the protective lacquer 55 can take place periodically at predefined time intervals, for example once a day, in order to seal a channel section that has been newly etched during the day or the entire already etched channel section 45 along the channel wall 46. In the latter case, the entire previous sealing of the channel section 45 is removed by the use of an organic solvent, for example, and a new sealing is applied, extending to just before the etching front or just before the end face 47 of the channel section 45.

For sealing purposes, typically the entire substrate 25 is dipped into a suitable protective lacquer 55. In this case, it is necessary to leave free the end face 47 of the channel section 45 that forms the later etching front. This can be done by insertion of a probe 49 and mechanical cleaning with the aid of a scraper 56, as is illustrated highly schematically in FIG. 12. Alternatively, it is also possible to carry out irradiation using (laser) light in order to remove the protective lacquer 55 from the end face 47 of the channel section 45.

A UV-curing protective lacquer 55 can also be used for the sealing. In this case, a probe 49 that radiates toward the side, i.e. toward the circumferential channel wall 46, but not in the channel direction (Y-direction), i.e. not in the direction of the end face 47, can be inserted into the channel section 45. Finally, the non-cured protective lacquer 55 is rinsed out of the already etched channel section 45. Alternatively, a sponge or felt body impregnated with the protective lacquer 55 on a probe 49 can be inserted into the channel section 45. In this case, for example by the use of a spacer mandrel or the like, the protective lacquer 55 can then be prevented from wetting the end face 47 of the channel 31, i.e. the future etching front.

In the example shown in FIG. 13, instead of the wet-chemical etching illustrated in FIG. 7B, the channel 31 is etched in the substrate 25 with the aid of a reactive plasma 57, i.e. a liquid etching solution 44 is not required in this case. For the etching, in this example use is made of a plasma source 58 which generates the reactive plasma 57 in the form of reactive plasma species, in the form of oxygen radicals in the example shown.

In the example shown in FIG. 13, too, the etching rate AS at the end face 47 of the channel section 45 is increased, specifically by the reactive plasma 57 being fed to the end face 47 of the channel section 45. Since the channel 31 in FIG. 13 has a small diameter d of approximately 5 mm, but the plasma source 58 has a diameter of approximately 10 mm, this plasma source cannot be introduced into the channel section 45 with a probe 49. The plasma source 58 is therefore arranged in the vicinity of the entrance of the channel section 45 and remains outside the substrate 25.

In order to guide the reactive plasma 57 to the end face 47 of the channel section 45, in FIG. 13 use is made of a feed 59 in the form of a rigid small tube, the exit-side end of which is guided into the vicinity of the end face 47 of the channel section 45. As feed for the plasma or the plasma species 57, a hose or the like can also be used, the free, exit-side end of which is situated in the vicinity of the end face 47 of the channel 31. The hose can have ring-shaped or spiral reinforcing elements in order to enable its cross-section to be stabilized in conjunction with good flexibility. The feed 59 e.g. in the form of a small tube, tube or the like may need to be regularly exchanged, formed from an etching-resistant material or provided with an etching-resistant inner coating or inner lining in the example shown in FIG. 13.

For the case where the channel 31 or the channel section 45 has a larger diameter, the plasma source 58 on a probe 49 or the like can be inserted into the channel section 45 and be guided as far as the end face 47 of the channel section 45 in order to expose the end face 47 locally to the reactive plasma 57. Generating the reactive plasma 57 in direct proximity to the end face 47 of the channel section 45 is advantageous since losses of reactive species occur during transport via the feed device 59, with the result that the external plasma source illustrated in FIG. 13 needs to be designed to be correspondingly more powerful.

During the etching process, the feed device 59 or optionally the plasma source 58 can be periodically inserted into the channel section 45 and periodically removed again and the waste material can be purged. Alternatively, continuous or quasi-continuous purging can also be employed. The purging without a feed 59 or probe 49 introduced into the channel section 45 is preferably carried out using a liquid solution or using a liquid jet, and the purging with a feed 59 or probe 49 inserted is preferably carried out using a gas jet.

FIGS. 14A-14C describe a further possibility for purging the end face 47 of the channel section 45 and also the channel wall 46 adjoining the end face 47 of the channel section 45, and for freeing them of initially etched particles in the process. In the example shown in FIG. 14A, for this purpose, a fluid feed in the form of a flexible hose 60 is inserted into the channel section 45, which is curved in the example shown. A fluid flow 61 oriented in the direction of the end face 47 of the channel section 45 emerges at an exit-side end 60a of the flexible hose 60. The purging fluid of the fluid flow 61 can be water, for example.

In order to ensure efficient purging, the exit-side end 60a of the hose 60 should be arranged at a mean distance A′ of at least approximately 5 mm away from the end face 47 of the channel section 45, since this enables suitable swirling of the fluid flow 61 in the region of the end face 47 of the channel section 45. In addition, thorough purging of edge regions of the channel wall 46 of the channel section 45 is thereby achieved in order to detach particles that have not yet been completely separated from the channel wall 46. Such particles can e.g. be configured in lamellar fashion, have a considerable length of e.g. approximately 3 mm and adhere in particular to the top side of the channel wall 46. Such particles and bubbles can block the narrow gap between the top side of the channel wall 46 and the hose 60, thereby blocking the return flow of the purging fluid, which is why such particles should be removed with the fluid flow 61.

The exit-side end 60a of the flexible hose 60—depending on the outflow volume and the outflow pressure of the fluid flow 61—should be arranged at a mean distance A′ of not more than approximately 15 mm from the end face 47 of the channel section 45, since otherwise the return-flow effect of the particle-fluid mixture can no longer be maintained. In order to intensify the swirling and back-flow effect, if the hose 60 is caused to track the end face 47 of the channel section 45 during the production of the channel 31, the hose can be moved cyclically back and forth, the distance A′ of the exit-side end 60a of the hose 60 varying ideally in the optimum range of the distance A′ between 5 mm and 10 mm.

As is shown in FIG. 14B, for optimal incident flow against the end face 47 of the channel section 45, the exit-side end 60a of the hose 60 can have a nozzle 51 or an attachment, as has been described further above in association with FIG. 10. The nozzle 51 serves for atomizing the emerging fluid flow 61 into a significantly larger solid angle range than is the case in the example shown in FIG. 14A, in which no nozzle is mounted on the exit-side end 60a of the hose 60. A fluid movement independent of the orientation of the hose 60 is caused thereby and there is incident flow against the full circumference of the end face 47 of the channel section 45. Thus, an equivalent or mean incident-flow angle of the fluid flow 61 against the end face 47 of the channel section 45 is independent of the exact orientation of the exit-side end 60a of the hose 60.

The nozzle 51 or the hose attachment mounted on the exit-side end 60a can consist for example of a thin-walled, convexly curved film having a thickness of between approximately 10 μm and approximately 50 μm composed of a flexible, ductile and crack-resistant material, e.g. composed of high-grade steel, brass, a carbon composite, etc., which is provided with microholes. FIG. 14C shows a plan view of such a nozzle 51 having a multiplicity of microholes. The area proportion of the surface area of the nozzle 51 shown in FIG. 14C which is constituted by the holes should be greater than 50% in order to ensure a sufficient flow rate. Alternatively, the nozzle 51 can also consist of a close-meshed net, a fine-pored stopper or a membrane having a comparable atomization effect. In order to increase the atomization effect and bring about an optimized backward movement of the purging fluid, the hose 60 can be additionally perforated on its circumferential lateral surface in the region of the exit-side end 60a, as is indicated by the circular holes illustrated in FIG. 14B.

In order to increase the impact or erosion effect of the purging fluid on the end face 47 of the channel section 45 and on the channel wall 46, the fluid flow 61 can be repetitively switched on and off, i.e. intermittent purging can be effected. This enables effective removal of smaller particles near the end face 47 of the channel section 45 and also larger, thin-walled and lamellar particles e.g. on the top side of the channel wall 46, which become detached starting from a critical length of approximately 4 mm.

For the efficient purging of the end face 47 of the channel section 45 and of the channel wall 46 adjoining this end face, it is necessary for the etching front or the end face 47 of the channel section 45 to be continuously tracked by the flexible hose 60 described in FIGS. 14A-14C when it moves in the volume of the substrate 25. In this case, the flexible hose 60 may need to be inserted even into regions of the substrate 25 that are difficult to access. In order to achieve the effect that the hose 60 is inserted into the already formed channel section 45 without kinking, it is necessary for the force point for the tracking by the hose 60 to commence as near as possible to a rigid wall delimiting the channel section 45, and for the force direction to be oriented parallel to the initial course of the channel section 45. FIG. 15A illustrates this substantive matter on the basis of the transition between the inlet channel 33 drilled into the substrate 25 and the merging section 34b of the distributor channel 34 of the hollow structure 27 shown in FIGS. 5A and 5B.

The force point, indicated by a horizontal line in FIG. 15A, when the hose 60 is threaded into the merging section 34b of the distributor channel 34 should be as close as possible to the wall or the material edge of the inlet channel 33 at the transition to the merging section 34b and the force direction, indicated by an arrow in FIG. 15A, during the tracking by the hose 60 should be oriented as far as possible parallel to the longitudinal direction of the merging section 34b of the distributor channel 34. For the case where the force direction and the force point deviate significantly from the position and orientation shown in FIG. 15A, this inevitably results in kinking of the flexible hose 60 during insertion into the merging section 34b of the distributor channel 34, which possibly prevents further insertion and/or damages the hose 60.

For the kinking-free insertion and tracking of the hose 60 into the merging section 34b of the distributor channel 34, oriented at an angle of 90° with respect to the inlet channel 33, it is advantageous if the force point and the force direction for the feeding of the hose are displaced out of the substrate 25 toward the outside. For this purpose, it is advantageous if a stable and rigid connection is produced between the starting point of the merging section 34b of the distributor channel 34 and the hose 60.

Such a connection can be effected with the aid of a rigid guide element 62 shown in FIG. 15B. The guide element 62 has a rod-shaped section, the external diameter of which is slightly smaller than the diameter of the cylindrical inlet channel 33. The rigid guide element 62 also has an internal channel 63, the diameter of which is slightly larger than the diameter of the hose 60 to be guided. The guide element 62 is inserted by the rod-shaped section into the inlet channel 33. In this case, an opening of the internal channel 63, which opening is formed on the lateral surface of the rod-shaped section, is positioned opposite the opening of the merging section 34b of the distributor channel 34, virtually a positively locking engagement being formed. With the aid of the rigid guide element 62, the force point and the force direction for the feeding and the tracking of the hose 60 are displaced out of the substrate 25 outward to the end face of the rigid guide element 62 and insertion of the hose 60 without kinking is made possible.

The exact course of the channel 63 within the rigid guide element 62, the exit position and the exit angle of the internal channel 63 on the lateral surface of the rod-shaped section and also the shape or the geometry of the guide element 62 can be adapted or defined depending on the desired course of the hollow structure 27. In the example shown, the internal channel 63 runs along a longitudinal axis in the center of the guide element 62 and, at the free end of the rod-shaped section of the guide element 62, is guided tangentially out of the latter arcuately with a desired exit angle. The guide element 62 can be configured to be substantially rotationally symmetrical with respect to the longitudinal axis, but this is not absolutely necessary.

The guide element 62 has, adjoining the rod-shaped section, a section projecting laterally over the substrate 25 and having a slightly larger diameter than the rod-shaped section inserted into the inlet channel 33. This is advantageous since the shoulder formed between the rod-shaped section and the projecting section can serve as a stop surface during the insertion of the rigid guide element 62.

In order to guide away the return flow of the purging fluid between the hose 60 and the wall of the internal channel 63 in targeted fashion, in the example shown in FIG. 15B, a return-flow adapter 64 is mounted fluid- or water-tightly on the end face of the section of the guide element 62 projecting laterally over the substrate 25. The return-flow adapter 64 is used, at a slotted part of the internal channel 63, to guide away the flowing-back purging fluid laterally via a radial channel, indicated in FIG. 15B, to the lateral surface of the return-flow adapter 64 and to feed it to a fluid line, not depicted.

The rigid guide element 62 described further above can be produced monolithically for example by additive manufacturing e.g. with the aid of a 3D printing method. As material for the rigid guide element 62 which satisfies the requirements in respect of complexity and water-tightness, an Al—Si alloy can be used, for example. As has been described further above, the design of the guide element 62 produced by the 3D printing method can be adapted to the geometry of the hollow structure 27. By way of example, it is possible in this case to realize hose guides having different exit angles of the hose 60 from the lateral surface of the rigid guide component 62, these exit angles being adapted to the respective channel geometry. By way of example, it is possible to realize an exit angle of 90° with respect to the longitudinal axis of the rigid guide element 62. The return-flow adapter 64, too, can be produced by the 3D printing method. In contrast to the illustration in FIG. 15B, it is possible for the return-flow adapter 64 not to form a separate component, but rather to be integrated in the guide component 62.

It is possible for the guide element 62 to have a plurality of internal channels 63 separated from one another in order to enable simultaneous tracking of a plurality of hoses into a plurality of channel sections which are processed in parallel. In this case, the exit positions on the lateral surface of the rod-shaped section of the guide element 62 can be chosen differently in the longitudinal direction and/or in the circumferential direction or in the radial direction.

For automated tracking of the hose 60, it is possible to use a tracking device 65 as illustrated in FIG. 15B and in FIG. 15C. In the example shown, the tracking device 65 comprises a track roller 66a and a directly driven drive roller 66b. As is evident in FIG. 15C, the track roller 66a and the drive roller 66b have a grooved cross-sectional shape and the lateral surface cross-section is also adapted to the cross-section of the hose 60 in order to exert an effective contact pressure on the hose 60. Enough feed force for guiding the hose 60 can be applied thereby and critical indentation of the hose 60 can be prevented. For improved adhesion, the lateral surface of the guide roller 66a and of the drive roller 66b can additionally be roughened or knurled.

As is evident in FIG. 15B, for the tracking of the hose 60, the guide roller 66a and the drive roller 66b are arranged directly adjacent to the guide element 62 or to the return-flow adapter 64 in order to avoid kinking and to guide the hose 60 through the internal channel 63 of the rigid guide element 62 into the merging section 34b of the distributor channel 34. Alternatively, the tracking device 65 can also be positioned in the vicinity of the entrance of a respective channel of the hollow structure 27 without the use of the guide element 62.

The tracking device 65 comprising the guide roller 66a and the drive roller 66b shown in FIGS. 15B and 15C is generally sufficient for the tracking of the hose 60—analogously to endoscopic tools—if the channel 31 to be formed and an already formed channel section 45 runs substantially in a straight line or is slightly curved and has a radius of curvature of more than 10 mm. With the aid of the tracking device 65, the already inserted hose 60 can also be rapidly removed from the respective channel section 45.

In the case of channel walls 46 having smaller radii of curvature of less than 10 mm or channel courses having many changes of direction, difficulties occur during the feed, however, since the hose 60—prebent by the previous course of the channel section 45—is pressed against the outer side of the channel wall 46 in a rounded-off section and it is therefore necessary to apply a higher force for the feed. In addition, the front edge of the hose may get caught on the microscopically roughened channel wall 46 of the channel section 45. Owing to the limited contact pressure of the tracking device 65 described in FIGS. 15B and 15C, this may lead to slip or kinking of the hose 60, which prevents the further feed of the hose 60.

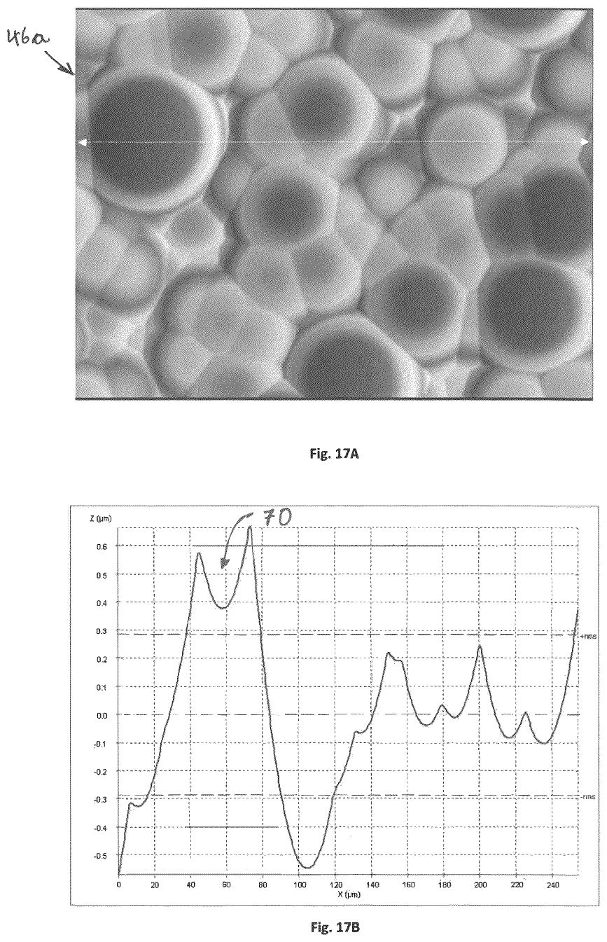

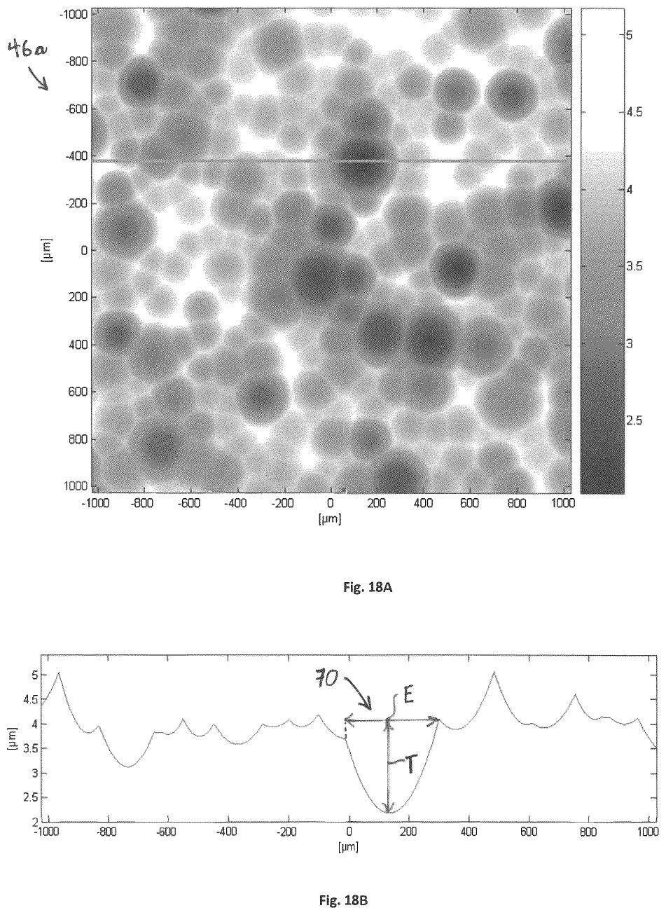

FIGS. 16A-16D show a tracking device which can be used to realize an active rotation of the hose 60 in parallel with the feed movement. The tracking device comprises an automatedly, e.g. pneumatically, electrically, . . . clampable chuck 67 which can be driven directly with a rotary spindle. In addition, the chuck 67 is mounted on a linear spindle indicated by a rectangle in FIGS. 16A-16D. In order that the end face 47 of the channel section 45 is tracked by the hose 60, the chuck 67, in the state released from the hose 60, is moved away from the rigid guide element 62 by a corresponding distance, typically amounting to a few millimeters, without moving the hose 60 in the process, as is illustrated in FIG. 16A. Afterward, the hose 60 is automatedly clamped in the chuck 67 and moved to the guide element 62 with the aid of the linear spindle, as is illustrated in FIG. 16B. The hose 60 is inserted by a programmable thrust length into the channel section 45 thereby. Afterward, the chuck 67 can be released automatedly again and the process can be repeated in order to guide the hose 60 step by step through the channel section 45.

Through a rotation of the entire chuck 67, the hose 60 can be rotated in addition to the linear feed movement if its exit-side end is guided along a greatly curved channel region, as is illustrated in FIG. 16C. The rotation enables the hose 60 to be introduced into the greatly curved channel region rotationally with as little friction as possible. In order that, during the return in the course of reapplying the chuck 67, the hose 60 is prevented from turning back or the hose 60 is prevented from being inadvertently withdrawn from the channel section 45, the tracking device comprises a further chuck 68, which is mounted in stationary fashion. The further chuck 68 is automatedly clamped before the chuck 67 is released for the return, as is indicated in FIG. 16D. The position of the hose 60 is not changed thereby during the reapplying. As soon as the chuck 67 has reached its starting position in the course of the return and once again clamps the hose 60, the further, stationary chuck 68 is released again. Thereby, too, automated continuous tracking of the hose 60 can be realized.

It is possible, in principle, to combine the chucks 67, 68 shown in FIGS. 16A-16D with the guide roller 66a and the drive roller 66b shown in FIGS. 15B and 15C in one and the same tracking device. The tracking device described further above enables the end face 47 of an already formed channel section 45 to be automatedly tracked by a hose 60, which is not self-movable, even in the case of complex hollow structures 27 or channels 31 having a high aspect ratio of length to diameter, which can be more than 10:1.

It should be pointed out that in order to simplify the illustration in FIG. 8 to FIGS. 16A-16D, only one channel section 45 has been shown on the substrate 25, but that in the case of a passage channel 31 as illustrated in FIGS. 7A and 7B, a respective channel section 45 having a channel wall 46 and with an etching front at its end face 47 is formed on both sides of the substrate 25. The etching step described further above, in particular with the increase in the etching rate, e.g. through the tracking of a hose 60, is typically carried out simultaneously on both channel sections of the passage channel 31.

FIG. 17A shows a micrograph of a portion of a surface 46a of the wall 46 of a channel 31 which was produced in the manner described in association with FIGS. 7A and 7B, i.e. by selective laser-induced etching. The channel 31, like the illustration in FIGS. 7A and 7B, is not a passage channel but rather the temperature control channel 31 illustrated in FIGS. 2A and 2B, which runs below the surface 25a of the substrate 25 to which the coating 26 is applied. For the production of the temperature control channel 31, which merges into the distributor channel 34 and respectively into the collector channel 36 at the two rounded-off sections 37a, 37b, the purging through the flexible hose 60 described further above in association with FIGS. 14A-14C to FIGS. 16A-16D was carried out.

As is evident in FIG. 17A, the surface 46a has a honeycomb-shaped surface structure having a plurality of substantially circular cutouts 70, wherein adjacent cutouts 70 run over into one another. As is evident with reference to FIG. 17A and with reference to FIG. 17B, which shows a profile section of the surface 46a of the wall 46 of the channel 31 along the horizontal line illustrated in a dashed manner in FIG. 17A, the cutouts 70 are crater-shaped, i.e. they each form a recess having a base enclosed by a ring-shapedly elevated wall, also referred to as crater edge. As is evident in the profile section in FIG. 17B, the crater edge of a respective crater-shaped cutout 70 is generally not of equal height at every point in the circumferential direction, but rather varies as a function of the position in the circumferential direction, which is attributable in particular to the running into one another or to the overlapping between the cutouts 70. The crater edges of the respective cutouts 70 form a netlike surface structure.

The surface 46a having the crater-shaped cutouts 70 shown in FIGS. 17A and 17B has a roughness Ra of less than 25 μm. The roughness Ra of the surface 46a of the wall 46 of the channel 31 is typically 20 μm or less, 10 μm or less, 5 μm or less, and can be in particular 2 μm or less. Both the temperature control channel 31 and also the distributor channels 34 and the collector channels 36 have a roughness Ra in the value range specified above and have a surface structure having the crater-shaped cutouts 70 described further above.

While FIGS. 17A and 17B show a comparatively small detail from the surface 46a with a lateral extent of approximately 250 μm by 190 μm, FIG. 18A illustrates a larger region of the surface 46a with a lateral extent of approximately 2000 μm by 2000 μm. FIG. 18B shows a profile section of the surface 46a from FIG. 18A along the horizontal line shown in FIG. 18A. FIG. 18B illustrates a particularly large and deep crater-shaped cutout 70, whose lateral extent L, which, in the example shown, corresponds to the diameter of the crater-shaped cutout 70, this cutout being circular in plan view, is approximately 300 μm. The depth T of the crater-shaped cutout 70 is approximately 2 μm. Generally, the crater-shaped cutouts 70, as a rule, have a maximum lateral extent L which is not greater than 500 μm, not greater than 450 μm or not greater than 400 μm. The maximum depth T of the crater-shaped cutouts 70 is typically not more than 20 μm, not more than 15 μm or not more than 10 μm.

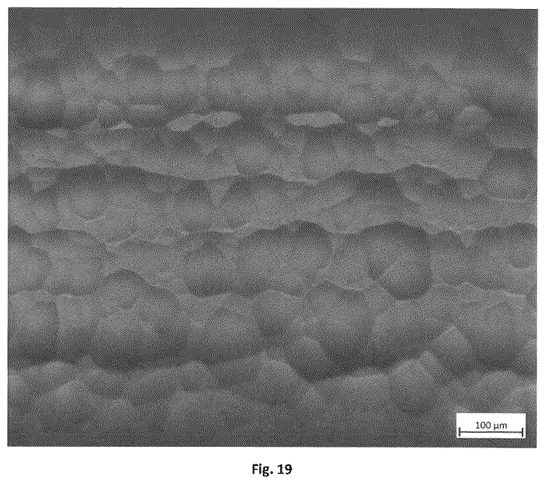

FIG. 19 shows the surface 46a of the wall 46 of the channel 31, on which an etching treatment was likewise carried out, wherein different laser parameters were used during the preceding irradiation. As is evident in FIG. 19, the surface 46a likewise has crater-shaped cutouts 70 which have a polygonal basic shape and form a honeycomb-like surface structure. The cutouts 70 of the surface 46a shown in FIG. 19 also have the properties regarding the maximum lateral extent E and the depth T described further above in association with FIGS. 17A and 17B and FIGS. 18A and 18B. The surface 46a illustrated in FIG. 19 additionally has the values specified further above for the roughness Rₐ.

What is claimed is:

1. A workpiece, comprising:
at least one hollow structure which runs in the workpiece and which is configured to receive a fluid flowing therein,
wherein the hollow structure has a first section and a second, adjacent section, which are oriented at an angle of between 60° and 120° with respect to one another,
wherein the hollow structure has a rounded-off section, at which the first section and the second section merge into one another, and
wherein a surface of a wall of the hollow structure in the first section, in the second section and/or in the rounded-off section has a roughness Rₐ of 25 μm or less.

2. The workpiece as claimed in claim 1 and configured as a substrate for a mirror configured for operation with extreme ultraviolet (EUV) radiation,
wherein the first section and the second, adjacent section are oriented at an angle of at least approximately 90° with respect to one another, and
wherein the surface of the wall of the hollow structure in the first section, in the second section and/or in the rounded-off section has a roughness Rₐ of 2 μm or less.

3. The workpiece as claimed in claim 1, wherein the surface of the wall of the hollow structure has cutouts.

4. The workpiece as claimed in claim 3, wherein the cutouts are configured to be crater-shaped.

5. The workpiece as claimed in claim 3, wherein adjacent ones of the cutouts run over into one another.

6. The workpiece as claimed in claim 3, wherein the cutouts at the surface of the wall of the hollow structure form a honeycomb-like surface structure.

7. The workpiece as claimed in claim 3, wherein the cutouts each have a maximum lateral extent of not more than 500 μm.

8. The workpiece as claimed in claim 3, wherein the cutouts each have a maximum depth of not more than 20 μm.

9. The workpiece as claimed in claim 1, wherein the first section, the second, adjacent section and the rounded-off section form channel sections of a channel configured to receive the flowing fluid.

10. The workpiece as claimed in claim 9, wherein the channel has a diameter of between 1 mm and 20 mm, and/or a length of at least 10 cm.

11. The workpiece as claimed in claim 9, wherein a cross-sectional area of the channel varies over a length of the channel by not more than +/−20%.

12. The workpiece as claimed in claim 1, wherein an R/D ratio between a radius of curvature R of the rounded-off section and a diameter D of the rounded-off section is between 2 and 6.

13. The workpiece as claimed in claim 1, wherein a diameter D of the rounded-off section is between 2 mm and 20 mm.

14. The workpiece as claimed in claim 1, wherein the hollow structure comprises a plurality of temperature control channels which run below a surface of the workpiece, and wherein the hollow structure comprises a fluid distributor connected to the temperature control channels via distributor channels and a fluid collector connected to the temperature control channels via collector channels.

15. The workpiece as claimed in claim 14, wherein the first section forms an end section of at least one of the temperature control channels adjoining at least one of the distributor channels and the second section forms a distributor channel section adjoining the end section and/or wherein the first section forms an end section of at least one of the temperature control channels adjoining a collector channel and wherein the second section forms a collector channel section adjoining the end section.

16. The workpiece as claimed in claim 14, wherein the fluid distributor forms an inlet channel from which the distributor channels branch off, and/or wherein the fluid collector forms an outlet channel from which the collector channels branch off.

17. The workpiece as claimed in claim 16, wherein the first section forms a merging section of at least one of the distributor channels adjacent to the inlet channel and wherein the second section forms a branching section of the inlet channel adjacent to the merging section and/or wherein the first section forms a merging section of at least one of the collector channels adjacent to the outlet channel and wherein the second section forms a branching section of the outlet channel adjacent to the merging section of the at least one of the collector channels.

18. The workpiece as claimed in claim 17, wherein the angle between the branching section of the inlet channel and the merging section of the distributor channel is greater than 90° and/or wherein the angle between the branching section of the outlet channel and the merging section of the collector channel is greater than 90°.

19. The workpiece as claimed in claim 1, formed of a material selected from the group consisting essentially of: fused silica and glass ceramic.

20. The workpiece as claimed in claim 1, formed of a material having a zero-crossing temperature between 0° C. and 100° C.

21. The workpiece as claimed in claim 20, formed of a material having a spatial variation of the zero-crossing temperature which is less than 3 K.

22. The workpiece as claimed in claim 1, configured as a monolith.

23. A mirror configured for operation with extreme ultraviolet light (EUV), comprising:
a workpiece as claimed in claim 1, and
a reflective coating for reflecting the EUV radiation, wherein the coating is applied to a surface of the substrate.

24. A method for at least partly forming a hollow structure in a workpiece by selective laser-induced etching, comprising:
focusing pulsed laser radiation into an irradiation volume in the workpiece, and
at least partly forming the hollow structure by selectively etching the workpiece in the irradiation volume.
